(19) United States
(12) Patent Application Publication
(10) Pub. No.: US 2026/0299408 A1
(43) Pub. Date: Oct. 1, 2026

(54) PHOTORESIST

(71) Applicant: TAIWAN SEMICONDUCTOR MANUFACTURING COMPANY, LTD., Hsinchu (TW)

(72) Inventors: Li-Po YANG, Hsinchu (TW); Wei-Han LAI, New Taipei City (TW); Kuan-Hsin LO, Nantou County (TW)

(73) Assignee: TAIWAN SEMICONDUCTOR MANUFACTURING COMPANY, LTD., Hsinchu (TW)

(21) Appl. No.: 19/097,691

(22) Filed: Apr. 1, 2025

(51) Int. Cl. G03F 7/004; G03F 7/20

(52) U.S. Cl. CPC G03F 7/0045; G03F 7/2006

(57) ABSTRACT

A photoresist composition comprises a polymer. The photoresist composition further comprises a photo acid generator (PAG). The photoresist composition further comprises a solvent. The polymer of the photoresist composition comprises a moiety in which the moiety comprises a radical quencher. The photo acid generator (PAG) is sensitive to extreme ultraviolet (EUV) radiation.

### BACKGROUND

As modem integrated circuits shrink in size, the associated features shrink in size as well. Lithography is a mechanism by which a pattern on a mask is projected onto a substrate such as a semiconductor wafer. In areas such as semiconductor photolithography, patterns are formed on the semiconductor wafer which incorporates minimum feature sizes under a resolution or critical dimension (CD). Semiconductor photolithography typically includes the steps of applying a coating of photoresist (also referred to as resist) on a top surface (e.g., a thin film stack) of a semiconductor wafer and exposing the photoresist to a pattern. The semiconductor wafer is then transferred to a developing chamber to remove the exposed resist, which is soluble to an aqueous developer solution. As a result, a patterned layer of photoresist exists on the top surface of the wafer.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a schematic view of an extreme ultraviolet (EUV) lithography tool with an LPP-based EUV radiation source, in accordance with some embodiments of the present disclosure.

FIG. 1B is a simplified schematic diagram of a detail of an extreme ultraviolet lithography tool according to an embodiment of the disclosure showing the exposure of photoresist coated substrate with a patterned beam of EUV light.

FIG. 1C is a sectional view of a EUV mask constructed in accordance with some embodiments of the present disclosure.

FIGS. 2A, 3-6 illustrate fragmentary cross-sectional side views of a semiconductor device in accordance with various aspects of the present disclosure.

FIG. 2B shows structures of the moiety RQ and the free additive in accordance with some embodiments.

FIG. 2C shows a diagram of lowest occupied molecular orbital (LUMO) versus highest occupied molecular orbital (HOMO)-LUMO band gap of the cation of the PAG in accordance with some embodiments.

FIG. 7 illustrates an example of a fin-type field effect transistor (FinFET) in a three-dimensional view, in accordance with some embodiments.

FIGS. 8A, 8B, 9-19C are cross-sectional views of intermediate stages in the manufacturing of FinFETs, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

When extreme ultraviolet (EUV) radiation pitch goes down, line width roughness (LWR) of photoresist is more sensitive. For example, exposure dose, photo acid generator (PAG)'s acid diffusion length, EUV radiation absorption of the photoresist and electron blur all play important factors to affect the LWR of the photoresist.

From EUV photoresist mechanism, electrons with high energy may be generated while EUV photons expose the photoresist. The primary electron can be about 80 V and can quickly collide nearby atoms to generate secondary electrons to release its energy. Based on the mean free path (MFP) curve, the secondary electrons with the low energy, such as about 1 eV to about 10 eV, can have more chance to pass through the matrix of the photoresist and survive for a longer time.

However, boundaries of the photoresist may be defined by the photomask. When the secondary electrons with long MFP arrive and pass through the boundary of the photoresist, some undesired chemical reactions may happen at unexposed area. For example, the extra photoacid may generate at the boundary of exposed regions of the photoresist, and photo decomposable quencher (PDQ) malfunction may happen at the boundary of the photoresist. Both reactions triggered by the secondary electrons may have negative impact on the roughness of the photoresist.

Embodiments of the present disclosure provide a novel photoresist including a radical quencher or radical scavenger. By including the radical quencher or radical scavenger in the photoresist, the reaction of the extra photoacid generated at the boundary of the exposed regions of the photoresist and the quencher malfunction at the boundary of the exposed regions of the photoresist may effectively be inhibited by the radical quencher or radical scavenger because the secondary electrons can react and be quenched by the radical quencher or radical scavenger.

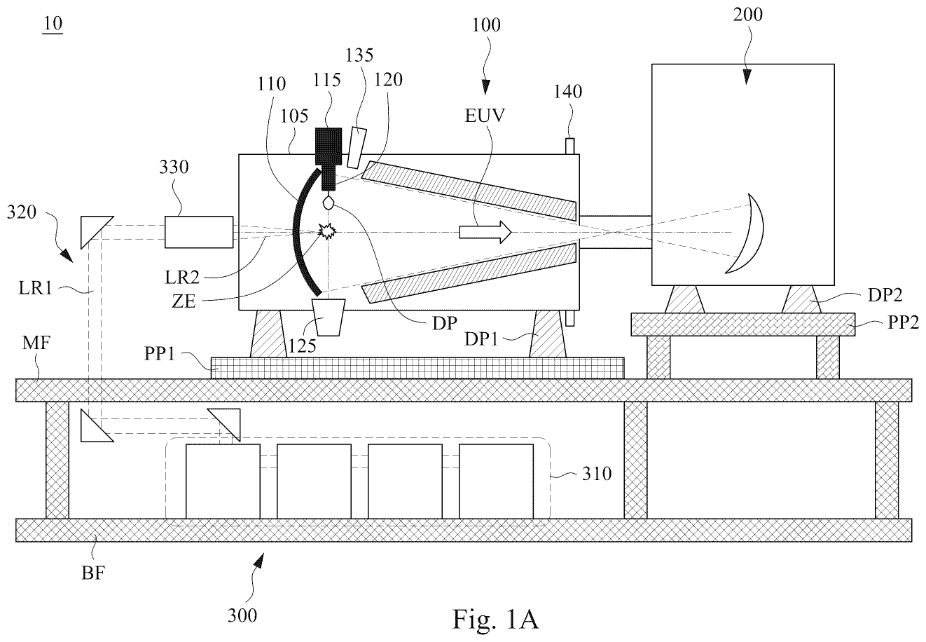

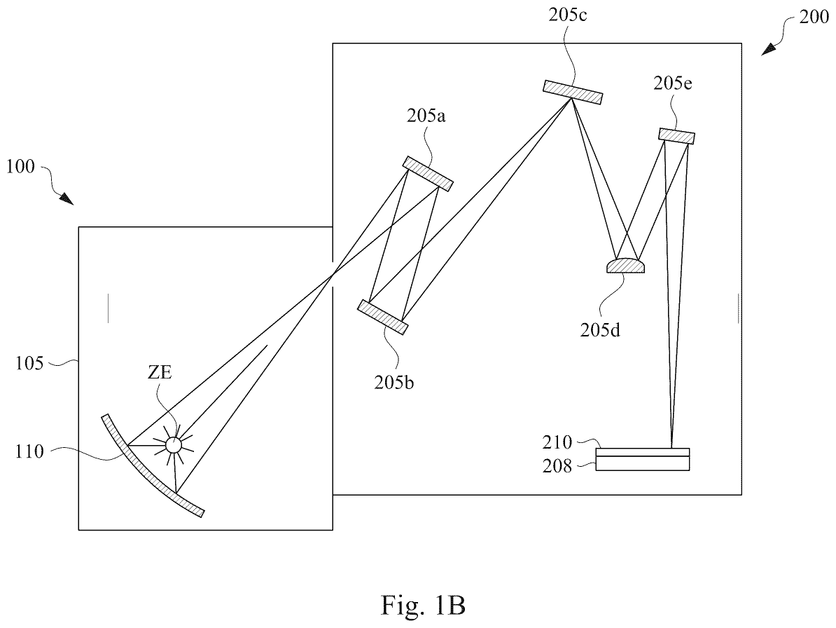

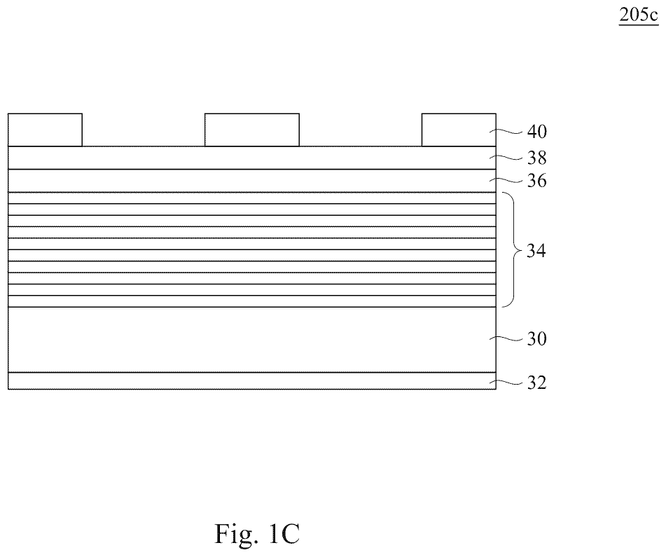

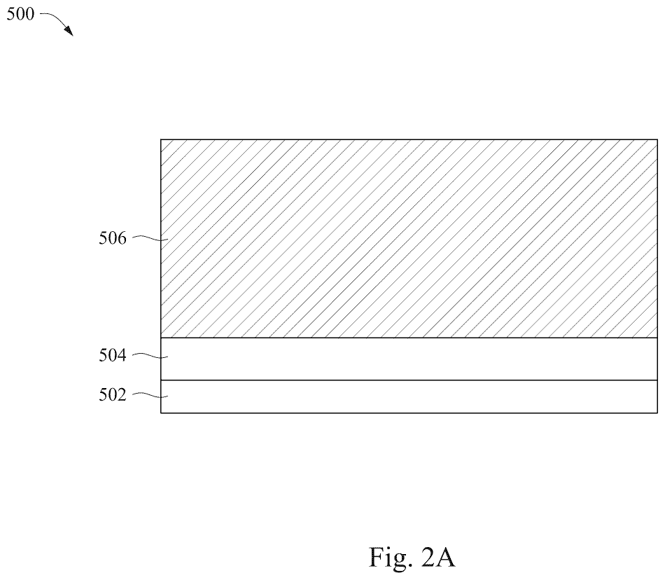

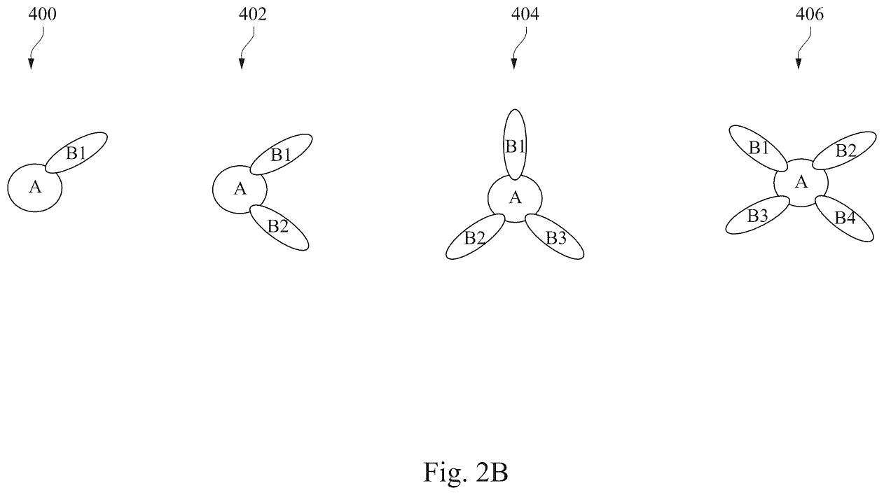

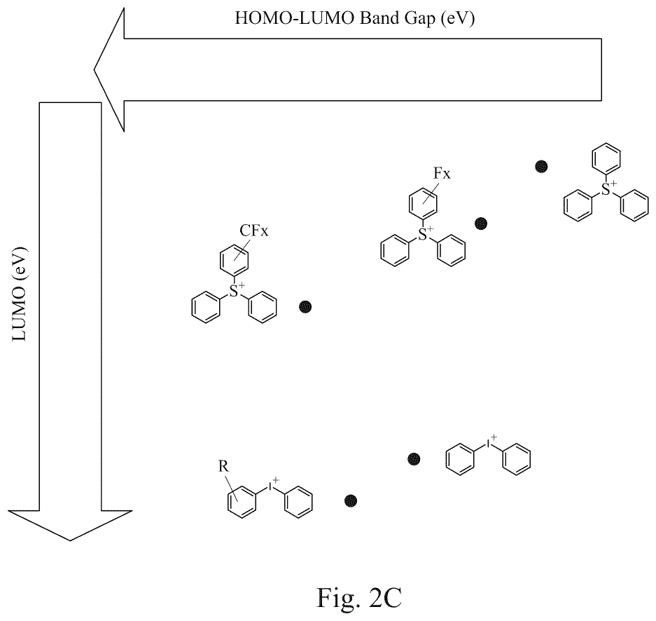

Therefore, the LWR of the photoresist used in EUV lithography can be improved. The various aspects of the present disclosure will be discussed below in greater detail with reference to FIGS. 1A-6. First, an EUV lithography system will be discussed below with reference to FIGS. 1A, 1B and 1C. Next, the details of the novel photoresist and the lithography process employing the photoresist will be discussed with reference to FIGS. 2A-6.

FIG. 1A is a schematic view diagram of an EUV lithography system 10, constructed in accordance with some embodiments. The EUV lithography system 10 may also be generically referred to as a scanner that is configured to perform lithography exposure processes with respective radiation source and exposure mode. The EUV lithography system 10 is designed to expose a photoresist layer by an EUV light or EUV radiation. The photoresist layer is a material sensitive to the EUV light. The EUV lithography system 10 employs a radiation source 100 to generate EUV light, such as EUV light having a wavelength ranging between about 1 nm and about 100 nm. In one particular example, the radiation source 100 generates an EUV light with a wavelength centered at about 13.5 nm. Accordingly, the radiation source 100 is also referred to as EUV radiation source 100.

The advanced lithography process, method, and materials described in the current disclosure can be used in many applications, including fin-type field effect transistors (FinFETs), gate-all-around (GAA) FETs. For example, the fins may be patterned to produce a relatively close spacing between features, for which the above disclosure is well suited. In addition, spacers used in forming fins of FinFETs can be processed according to the above disclosure.

To address the trend of the Moore's law for decreasing size of chip components and the demand of higher computing power chips for mobile electronic devices such as smart phones with computer functions, multi-tasking capabilities, or even with workstation power. Smaller wavelength photolithography exposure systems are desirable. Extreme ultraviolet (EUV) photolithography technique uses an EUV radiation source to emit an EUV light ray with wavelength of about 13.5 nm. Because this wavelength is also in the x-ray radiation wavelength region, the EUV radiation source is also called a soft x-ray radiation source. The EUV light rays emitted from a laser-produced plasma (LPP) are collected by a collector mirror and reflected toward a patterned mask.

FIG. 1A is a schematic view of an EUV lithography tool with an LPP-based EUV radiation source, in accordance with some embodiments of the present disclosure. The EUV lithography system includes an EUV radiation source 100 to generate EUV radiation, an exposure device 200, such as a scanner, and an excitation laser source 300. As shown in FIG. 1A, in some embodiments, the EUV radiation source 100 and the exposure device 200 are installed on a main floor MF of a clean room, while the excitation laser source 300 is installed in a base floor BF located under the main floor MF. Each of the EUV radiation source 100 and the exposure device 200 are placed over pedestal plates PP1 and PP2 via dampers DP1 and DP2, respectively. The EUV radiation source 100 and the exposure device 200 are coupled to each other by a coupling mechanism, which may include a focusing unit.

The EUV lithography tool is designed to expose a resist layer to EUV light (also interchangeably referred to herein as EUV radiation). The resist layer is a material sensitive to the EUV light. The EUV lithography system employs the EUV radiation source 100 to generate EUV light, such as EUV light having a wavelength ranging between about 1 nm and about 100 nm. In one particular example, the EUV radiation source 100 generates an EUV light with a wavelength centered at about 13.5 nm. In the present embodiment, the EUV radiation source 100 utilizes a mechanism of laser-produced plasma (LPP) to generate the EUV radiation.

The exposure device 200 includes various reflective optic components, such as convex/concave/flat mirrors, a mask holding mechanism including a mask stage, and wafer holding mechanism. The EUV radiation EUV generated by the EUV radiation source 100 is guided by the reflective optical components onto a mask secured on the mask stage. In some embodiments, the mask stage includes an electrostatic chuck (e-chuck) to secure the mask.

FIG. 1B is a simplified schematic diagram of a detail of an extreme ultraviolet lithography tool according to an embodiment of the disclosure showing the exposure of photoresist coated substrate 210 secured on a substrate stage 208 of the exposure device 200 with a patterned beam of EUV light. Formation method and composition of the photoresist can be similar to the photoresist layer (506 as discussed below with regard to FIG. 2A) The exposure device 200 is an integrated circuit lithography tool such as a stepper, scanner, step and scan system, direct write system, device using a contact and/or proximity mask, etc., provided with one or more optics 205a, 205b, for example, to illuminate a patterning optic 205c, such as a reticle, with a beam of EUV light, to produce a patterned beam, and one or more reduction projection optics 205d, 205e, for projecting the patterned beam onto the photoresist coated substrate 210. A mechanical assembly (not shown) may be provided for generating a controlled relative movement between the photoresist coated substrate 210 and the patterning optic 205c. As further shown in FIG. 1C, the EUVL tool includes an EUV radiation source 100 including an EUV light radiator ZE emitting EUV light in a chamber 105 that is reflected by a collector 110 along a path into the exposure device 200 to irradiate the photoresist coated substrate 210.

As used herein, the term “optic” is meant to be broadly construed to include, and not necessarily be limited to, one or more components which reflect and/or transmit and/or operate on incident light, and includes, but is not limited to, one or more lenses, windows, filters, wedges, prisms, grisms, gradings, transmission fibers, etalons, diffusers, homogenizers, detectors and other instrument components, apertures, axicons and mirrors including multi-layer mirrors, near-normal incidence mirrors, grazing incidence mirrors, specular reflectors, diffuse reflectors and combinations thereof. Moreover, unless otherwise specified, the term “optic”, as used herein, is directed to, but not limited to, components which operate solely or to advantage within one or more specific wavelength range(s) such as at the EUV output light wavelength, the irradiation laser wavelength, a wavelength suitable for metrology or any other specific wavelength. In various embodiments of the present disclosure, the photoresist coated substrate 210 is a semiconductor wafer, such as a silicon wafer or other type of wafer to be patterned. The EUVL tool further includes other modules or is integrated with (or coupled with) other modules in some embodiments.

As shown in FIG. 1A, the EUV radiation source 100 includes a target droplet generator 115 and a collector 110, enclosed by a chamber 105. For example, the collector 110 is a laser-produced plasma (LPP) collector. In various embodiments, the target droplet generator 115 includes a reservoir to hold a source material and a nozzle 120 through which target droplets DP of the source material are supplied into the chamber 105.

In some embodiments, the target droplets DP are metal droplets of tin (Sn), lithium (Li), or an alloy of Sn and Li. In some embodiments, the target droplets DP each have a diameter in a range from about 10 microns (μm) to about 100 μm. For example, in an embodiment, the target droplets DP are tin droplets, having a diameter of about 10 μm to about 100 μm. In other embodiments, the target droplets DP are tin droplets having a diameter of about 25 μm to about 50 μm. In some embodiments, the target droplets DP are supplied through the nozzle 120 at a rate in a range from about 50 droplets per second (i.e., an ejection-frequency of about 50 Hz) to about 50,000 droplets per second (i.e., an ejection-frequency of about 50 kHz).

Referring back to FIG. 1A, an excitation laser LR2 generated by the excitation laser source 300 is a pulse laser. The laser pulses LR2 are generated by the excitation laser source 300.

The excitation laser source 300 may include a laser generator 310, laser guide optics 320 and a focusing apparatus 330. In some embodiments, the laser generator 310 includes a carbon dioxide (CO₂) or a neodymium-doped yttrium aluminum garnet (Nd:YAG) laser source with a wavelength in the infrared region of the electromagnetic spectrum. For example, the laser generator 310 has a wavelength of about 9.4 μm or about 10.6 μm, in an embodiment. The laser light LR1 generated by the laser generator 310 is guided by the laser guide optics 320 and focused into the excitation laser LR2 by the focusing apparatus 330, and then introduced into the EUV radiation source 100.

In some embodiments, the excitation laser LR2 includes a pre-heat laser and a main laser.

In such embodiments, the pre-heat laser pulse (interchangeably referred to herein as the “pre-pulse”) is used to heat (or pre-heat) a given target droplet to create a low-density target plume with multiple smaller droplets, which is subsequently heated (or reheated) by a pulse from the main laser, generating increased emission of EUV light.

In various embodiments, the pre-heat laser pulses have a spot size about 100 μm or less, and the main laser pulses have a spot size in a range of about 150 μm to about 300 μm. In some embodiments, the pre-heat laser and the main laser pulses have a pulse-duration in the range from about 10 ns to about 50 ns, and a pulse-frequency in the range from about 1 kHz to about 100 kHz. In various embodiments, the pre-heat laser and the main laser have an average power in the range from about 1 kilowatt (kW) to about 50 kW. The pulse-frequency of the excitation laser LR2 is matched with (e.g., synchronized with) the ejection-frequency of the target droplets DP in an embodiment.

The excitation laser LR2 is directed through windows (or lenses) into the zone of excitation ZE in front of the collector 110. The windows are made of a suitable material substantially transparent to the laser beams. A droplet generator 115 is turned on to eject the target droplets DP toward the zone of excitation ZE in front of the collector 110. The generation of the pulse lasers is synchronized with the ejection of the target droplets DP through the nozzle 120. As the target droplets move through the excitation zone, the pre-pulses heat the target droplets and transform them into low-density target plumes. A delay between the pre-pulse and the main pulse is controlled to allow the target plume to form and to expand to an optimal size and geometry. In various embodiments, the pre-pulse and the main pulse have the same pulse-duration and peak power. When the main pulse heats the target plume, a high-temperature plasma is generated. The plasma emits EUV radiation EUV, which is collected by the collector 110. The collector 110 further reflects and focuses the EUV radiation for the lithography exposing processes performed through the exposure device 200. The droplet catcher 125 is used for catching excessive target droplets. For example, some target droplets may be purposely missed by the laser pulses.

In some embodiments, the collector 110 is designed with a proper coating material and shape to function as a mirror for EUV collection, reflection, and focusing. In some embodiments, the collector 110 is designed to have an ellipsoidal geometry. In some embodiments, the coating material of the collector 110 is similar to the reflective multilayer of the EUV mask. In some examples, the coating material of the collector 110 includes a ML (such as a plurality of Mo/Si film pairs) and may further include a capping layer (such as Ru) coated on the ML to substantially reflect the EUV light. In some embodiments, the collector 110 may further include a grating structure designed to effectively scatter the laser beam directed onto the collector 110. For example, a silicon nitride layer is coated on the collector 110 and is patterned to have a grating pattern.

In the present disclosure, the terms mask, photomask, and reticle are used interchangeably. In the present embodiment, the patterning optic 205c is a reflective mask 205c.

The reflective mask 205c also includes a reflective ML deposited on the substrate. The ML includes a plurality of film pairs, such as molybdenum-silicon (Mo/Si) film pairs (e.g., a layer of molybdenum above or below a layer of silicon in each film pair). Alternatively, the ML may include molybdenum-beryllium (Mo/Be) film pairs, or other suitable materials that are configurable to highly reflect the EUV light.

The mask 205c may further include a capping layer, such as ruthenium (Ru), disposed on the ML for protection. The mask 205c further includes an absorption layer deposited over the ML. The absorption layer is patterned to define a layer of an integrated circuit (IC), the absorber layer is discussed below in greater detail according to various aspects of the present disclosure. Alternatively, another reflective layer may be deposited over the ML and is patterned to define a layer of an integrated circuit, thereby forming a EUV phase shift mask.

The mask 205c and the method making the same are further described in accordance with some embodiments. In some embodiments, the mask fabrication process includes two operations: a blank mask fabrication process and a mask patterning process. During the blank mask fabrication process, a blank mask is formed by deposing suitable layers (e.g., reflective multiple layers) on a suitable substrate. The blank mask is then patterned during the mask patterning process to achieve a desired design of a layer of an integrated circuit (IC). The patterned mask is then used to transfer circuit patterns (e.g., the design of a layer of an IC) onto a semiconductor wafer. The patterns can be transferred over and over onto multiple wafers through various lithography processes. A set of masks is used to construct a complete IC.

One example of the reflective mask 205c is shown in FIG. 1C. The reflective mask 205c in the illustrated embodiment is a EUV mask, and includes a substrate 30 made of a LTEM. The LTEM material may include TiO₂ doped SiO₂, and/or other low thermal expansion materials known in the art. In some embodiments, a conductive layer 32 is additionally disposed under on the backside of the LTEM substrate 30 for the electrostatic chucking purpose. In one example, the conductive layer 32 includes chromium nitride (CrN), though other suitable compositions are possible.

The reflective mask 205c includes a reflective multilayer (ML) structure 34 disposed over the LTEM substrate 30. The ML structure 34 may be selected such that it provides a high reflectivity to a selected radiation type/wavelength. The ML structure 34 includes a plurality of film pairs, such as Mo/Si film pairs (e.g., a layer of molybdenum above or below a layer of silicon in each film pair). Alternatively, the ML structure 34 may include Mo/Be film pairs, or any materials with refractive index difference being highly reflective at EUV wavelengths.

Still referring to FIG. 1C, the EUV mask 205c also includes a capping layer 36 disposed over the ML structure 34 to prevent oxidation of the ML. The EUV mask 205c may further include a buffer layer 38 disposed above the capping layer 36 to serve as an etching-stop layer in a patterning or repairing process of an absorption layer, which will be described later. The buffer layer 38 has different etching characteristics from the absorption layer disposed thereabove. The buffer layer 38 includes ruthenium (Ru), Ru compounds such as RuB, RuSi, chromium (Cr), chromium oxide, and chromium nitride in various examples.

The EUV mask 205c also includes an absorber layer 40 (also referred to as an absorption layer) formed over the buffer layer 38. In some embodiments, the absorber layer 40 absorbs the EUV radiation directed onto the mask. In various embodiments, the absorber layer may be made of tantalum boron nitride (TaBN), tantalum boron oxide (TaBO), or chromium (Cr), Radium (Ra), or a suitable oxide or nitride (or alloy) of one or more of the following materials: Actium, Radium, Tellurium, Zinc, Copper, and Aluminum.

FIGS. 2A, 3-6 illustrate fragmentary cross-sectional side views of a semiconductor device 500 in accordance with various aspects of the present disclosure. In FIGS. 2A, 3-6, the semiconductor device 500 can be fabricated using a photoresist layer 506. Referring to FIG. 2A, a target layer 504 is formed over a substrate 502, and a photoresist composition is applied over the target layer 504 to form a photoresist layer 506. The semiconductor device 500 may include an integrated circuit (IC) chip, system on chip (SoC), or portion thereof, and may include various passive and active microelectronic devices such as resistors, capacitors, inductors, diodes, metal-oxide semiconductor field effect transistors (MOSFET), complementary metal-oxide semiconductor (CMOS) transistors, bipolar junction transistors (BJT), laterally diffused MOS (LDMOS) transistors, high power MOS transistors, or other types of transistors.

In some embodiments, the substrate 502 is a silicon substrate doped with a p-type dopant such as boron (for example a p-type substrate). Alternatively, the substrate 502 could be another suitable semiconductor material. For example, the substrate 502 may be a silicon substrate that is doped with an n-type dopant such as phosphorous or arsenic (an n-type substrate). The substrate 502 could include other elementary semiconductors such as germanium and diamond.

The substrate 502 could optionally include a compound semiconductor and/or an alloy semiconductor. Further, the substrate 502 could include an epitaxial layer (epi layer), may be strained for performance enhancement, and may include a silicon-on-insulator (SOI) structure.

In some embodiments, the substrate 502 is substantially conductive or semi-conductive.

The electrical resistance may be less than about 103 ohm-meter. In some embodiments, the substrate 502 contains metal, metal alloy, or metal nitride/sulfide/selenide/oxide/silicide with the formula MXₐ, where M is a metal, and X is N, S, Se, O, Si, and where “a” is in a range from about 0.4 to 2.5. For example, the substrate 501 may contain Ti, Al, Co, Ru, TiN, WN₂, or TaN.

In some other embodiments, the substrate 502 contains a dielectric material with a dielectric constant in a range from about 1 to about 40. In some other embodiments, the substrate 502 contains Si, metal oxide, or metal nitride, where the formula is MX_{b}, wherein M is a metal or Si, and X is N or O, and wherein “b” is in a range from about 0.4 to 2.5. For example, the substrate 502 may contain SiO₂, silicon nitride, aluminum oxide, hafnium oxide, or lanthanum oxide.

The target layer 504 can be patterned via a lithography process and as such may also be referred to as a patternable layer. In an embodiment, the target layer 504 includes a dielectric material, such as silicon oxide or silicon nitride. In another embodiment, the target layer 504 includes metal. In yet another embodiment, the target layer 504 includes a semiconductor material.

In some embodiments, the target layer 504 has different optical properties than photoresist. For example, the target layer 504 has a different n, k, or T value from photoresist. In some embodiments, the target layer 504 and the overlying photoresist layer have different etching resistance. In some embodiments, the target layer 504 contains an etching resistant molecule. It is understood that the substrate 502 and the target layer 504 may each include additional suitable material compositions in other embodiments.

In some embodiments, the photoresist layer 506 can be spin coated on the target layer 504 on the substrate 502. In some embodiments, the photoresist composition of the photoresist layer 506 can include a polymer including a plurality of monomers, a photo acid generator (PAG) and a solvent. The solvent may include an appropriate organic solvent for an adjustment of its viscosity.

In some embodiments, the polymer can include formulae (a1)-(a4) below:

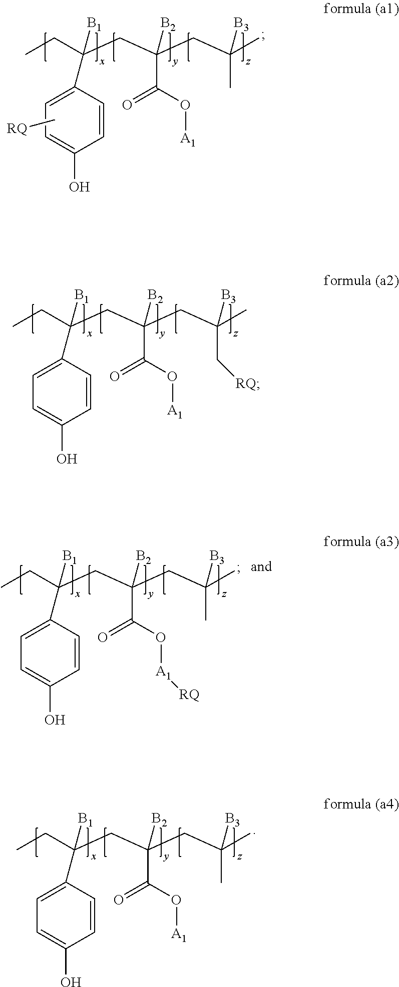

In the formulae (a1), (a2), (a3), the polymer can be an EUV sensitive resist including a moiety RQ including a radical quencher or radical scavenger. In the formulae (a1), (a2), (a3), the polymer comprises a phenolic group. During a subsequent exposing process, the reaction of extra photoacids generated at the boundary of the exposed regions of the photoresist layer 506 and the quencher malfunction at the boundary of the exposed regions of the photoresist layer 506 may be effectively inhibited by the radical quencher or radical scavenger of the moiety RQ because the secondary electrons can react with the radical quencher or radical scavenger and be quenched. Therefore, the LWR of the photoresist layer 506 used in EUV lithography can be improved.

As the formulae (a1), (a2), (a3) shown, for example, the moiety RQ can be bonded as one of the monomers of the polymer or as a functional unit of the polymer of the photoresist composition. In the formulae (a1), (a2), (a3), B₁, B₂, B₃ can be CH₃ or H, A₁ can be acid labile group (ALG), and x+y+z=1. In some embodiments, the photoresist composition of the photoresist layer 506 can include the polymer with the formula (a4) and a free additive in which the free additive includes a radical quencher or radical scavenger. In other words, the free additive may not be bonded to the polymer.

FIG. 2B shows structures 400, 402, 404, 406 of the moiety RQ and the free additive in accordance with some embodiments. Reference is made to FIG. 2B. In some embodiments, each of the moiety RQ and the additive may include a core A, and one or more groups connected, as a substituent, to the core A. For example, in the structure 400, the moiety RQ and the free additive can include the core A and one group B1 connected, as a substituent, to the core A. In the structure 402, the moiety RQ and the free additive can include the core A and two groups B1, B2 connected, as a substituent, to the core A. In the structure 404, the moiety RQ and the free additive can include the core A and three groups B1, B2, B3 connected, as a substituent, to the core A. In the structure 406, the moiety RQ and the free additive can include the core A and four groups B1, B2, B3, B4 connected, as a substituent, to the core A. In some embodiments, the core A is a core structure containing C3 to C80 saturated or unsaturated hydrocarbon ring or C2 to C80 heterocyclic saturated or unsaturated hydrocarbon. In some embodiments, the groups B1, B2, B3, B4 can include a bond dissociation energy (BDE) in a range from about 10 kcal/mol to about 1000 kcal/mol.

In some embodiments, the groups B1, B2, B3, B4 may include OH, SH, SeH, TeH, O—R, S—R, Se—R, Te—R, NH₂, NHR, NR₂, where in O—R, S—R, Se—R, Te—R, NHR, NR₂, R is C1 to C20 alkyl group, cycloalkyl group, hydroxylalkyl group, alkoxy group, alkoxyl alkyl group, acetyl group, acetylalkyl group, carboxyl group, alky carboxyl group, cycloalkyl carboxyl group, C2 to C20 saturated or unsaturated hydrocarbon ring, C1 to C20 hetero hydrocarbon, C2 to C20 heterocyclic hydrocarbon. In some embodiments, the free additive can include a molecule weight (Mw) in a range from about 50 to about 5000, and have a weight percentage (wt %) in a range from about 1 ppm to about 50 wt %. In the formulae (a1), (a2), (a3), the moiety RQ may be bonded to the polymer through the core A or through the groups B1, B2, B3, B4 and have a proportion ratio of x in the polymer in which 0<x≤100%. In some embodiments, the additive may have a formula (b1):

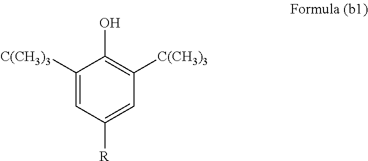

where in the formula (b1), R is C1 to C20 alkyl group, cycloalkyl group, hydroxylalkyl group, alkoxy group, alkoxyl alkyl group, acetyl group, acetylalkyl group, carboxyl group, alky carboxyl group, cycloalkyl carboxyl group, C2 to C20 saturated or unsaturated hydrocarbon ring, C1 to C20 hetero hydrocarbon, C2 to C20 heterocyclic hydrocarbon. The free additive having the formula (b1) can undergo a chemical reaction (c1), which shows a mechanism of deactivation of alkoxy radicals by phenolic antioxidants (PO·):

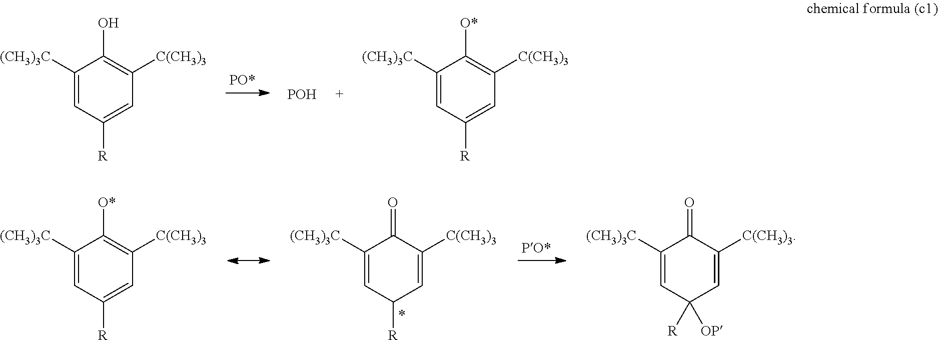

In the chemical reaction (c1), the free additive having the formula (b1) can become a deactivation radical source by hydrogen abstraction and form, for example, an alkoxy radial. Using the phenolic antioxidants (PO·), two radical sources can be effectively “quencher” out. In some embodiments, R in the chemical formula (bi) can be C1 to C20 alkyl group, cycloalkyl group, hydroxylalkyl group, alkoxy group, alkoxyl alkyl group, acetyl group, acetylalkyl group, carboxyl group, alky carboxyl group, cycloalkyl carboxyl group, C2 to C20 saturated or unsaturated hydrocarbon ring, C1 to C20 hetero hydrocarbon, C2 to C20 heterocyclic hydrocarbon.

For chemical amplify resist, the PAG will become an acid after exposure to radiation. The acid will initiate the leaving of acid labile groups (ALG) of the polymer during the post-exposure bake (PEB) process. The leaving of the ALG will produce an acid for initiating leaving of subsequent ALG from the polymer. Such a chain reaction will be terminated only when the acid produced comes in contact with a base, also referred to as a base quencher or quencher. In some embodiments, the PAG or PDQ of the photoresist composition can be triggered by the EUV and can include a cation, such as triphenyl sulfonium (S⁻R3⁺) or biphenyl iodonium (I⁻R²⁺). In some embodiments, the PAG or the PDQ can have a highest occupied molecular orbital (HOMO)-lowest occupied molecular orbital (LUMO) energy gap within a range from about 0.01 eV to about 80 eV. FIG. 2C shows a diagram of LUMO versus HOMO-LUMO band gap of the cation of the PAG in accordance with some embodiments. Reference is made to FIG. 2C. In some embodiments, the PAG and the PDQ may include the cation including the formulae (d1)-(d4).

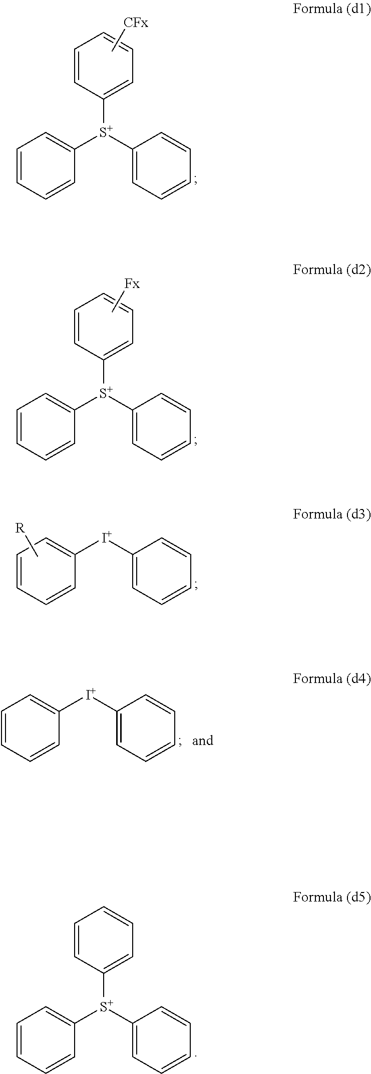

In some embodiments, the PAG can include the formula (e1):

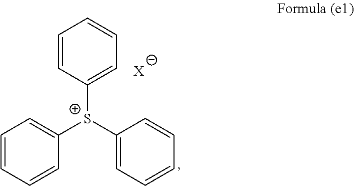

in which X is an anion such as R—SO₃⁻. In some embodiments, the PDQ can include the formula (d1) in which X is R—COO⁻. In some embodiments, R in the R—SO₃⁻ and R—COO⁻ may be a hydrogen atom, an alkyl group having 1 to 20 carbon atoms, an aminoalkyl group having 1 to 20 carbon atoms, a hydroxyalkyl group having 1 to 20 carbon atoms, or a substituted or unsubstituted aryl group having 1 to 20 carbon atoms. The PAG or the PDQ having the formula (d1) can undergo a chemical reaction (c2), which shows a mechanism of acid generation of the PAG by electrons:

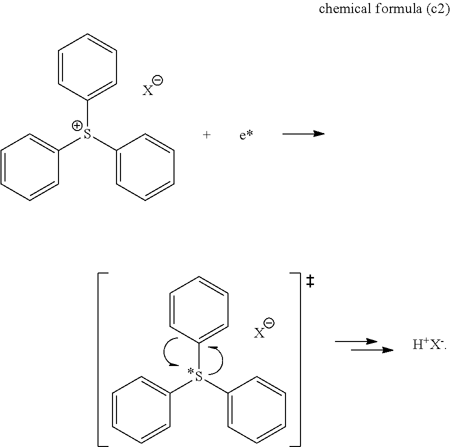

Referring back to FIG. 2A, a post apply bake (PAB) (or soft bake) can be performed to the photoresist layer 506 to reduce the solvent in the photoresist layer 506.

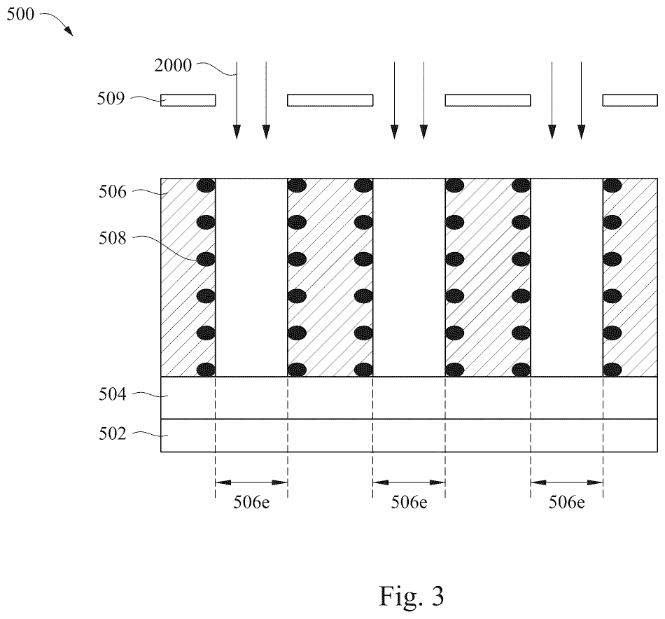

Reference is made to FIG. 3. An exposure process 2000 can be performed to the photoresist layer 506. The photoresist layer 506 can have exposed regions 506e which are uncovered by a mask 509 including the design of a layer of an IC and thus are exposed by the exposure process 2000. In some embodiments, the photoresist layer 506 can be exposed to EUV radiation during the exposure process 2000. As discussed previously with regard to FIG. 3, extra photoacid 508 generated at the boundary of the exposed region 506e of photoresist layer 506 and the quencher malfunction at the boundary of the exposed region 506e of the photoresist layer 506 may be effectively inhibited by the radical quencher or radical scavenger of the photoresist layer 506 because the secondary electrons can react therewith and be quenched. In some embodiments, a post-exposure bake (PEB) may then be performed to the photoresist layer 506.

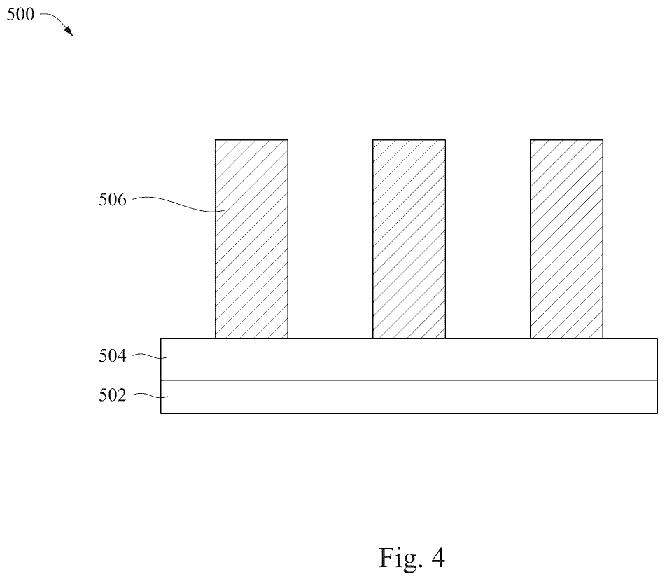

Reference is made to FIG. 4. In some embodiments, the photoresist layer 506 is developed, such as using a developer, forming the patterned photoresist layer 506. Since the extra photoacid 508 generated at the boundary of the exposed region 506e of photoresist layer 506 and the quencher malfunction at the boundary of the exposed region 506e of the photoresist layer 506 may be inhibited by the radical quencher or radical scavenger of the photoresist layer 506, the LWR of the photoresist layer 506 can be improved.

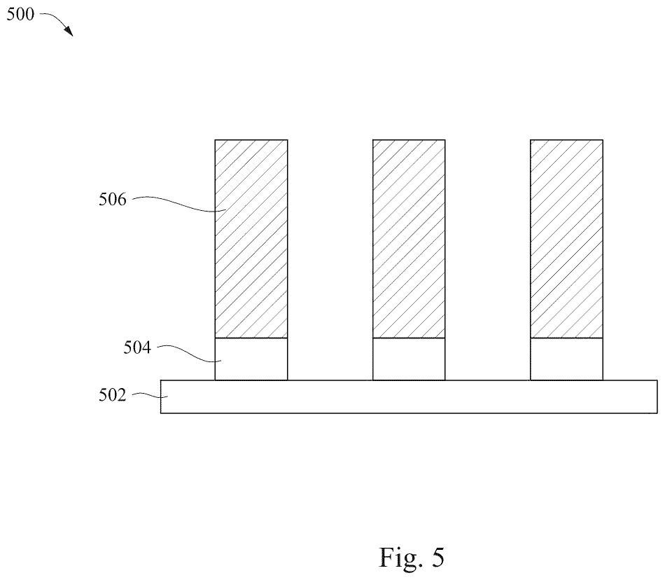

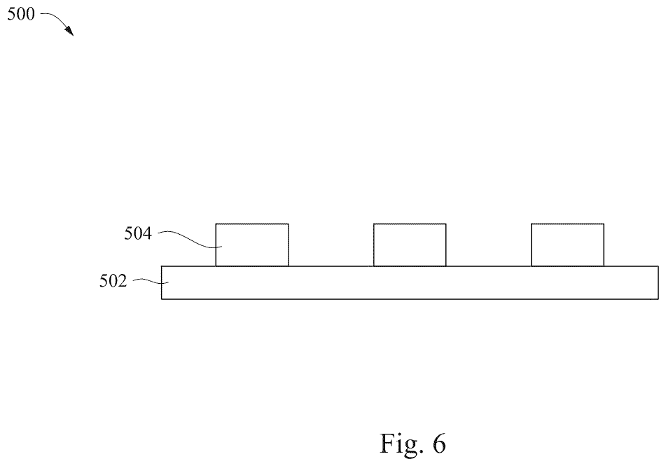

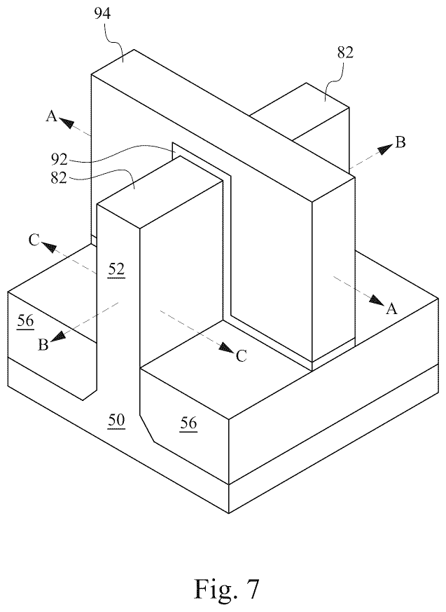

Reference is made to FIG. 5. The target layer 504 can be etched by using the patterned photoresist layer 506 as an etch mask in some embodiments. The patterned photoresist layer 506 is then removed, for example, by ashing. The ashing operation such as a plasma ash removes the remaining patterned photoresist layer 506, and a wet clean may be performed to clean the etch residues. The resulting structure is shown in FIG. 6.

FIG. 7 illustrates an example of a FinFET in a three-dimensional view, in accordance with some embodiments. The FinFET comprises a fin 52 on a substrate 50 (e.g., a semiconductor substrate). Isolation regions 56 are disposed in the substrate 50, and the fin 52 protrudes above and from between neighboring isolation regions 56. Although the isolation regions 56 are described/illustrated as being separate from the substrate 50, as used herein the term “substrate” may be used to refer to just the semiconductor substrate or a semiconductor substrate inclusive of isolation regions. Additionally, although the fin 52 is illustrated as a single, continuous material as the substrate 50, the fin 52 and/or the substrate 50 may comprise a single material or a plurality of materials. In this context, the fin 52 refers to the portion extending between the neighboring isolation regions 56.

A gate dielectric layer 92 is along sidewalls and over a top surface of the fin 52, and a gate electrode 94 is over the gate dielectric layer 92. Source/drain regions 82 are disposed in opposite sides of the fin 52 with respect to the gate dielectric layer 92 and gate electrode 94. FIG. 7 further illustrates reference cross-sections that are used in later figures. Cross-section A-A is along a longitudinal axis of the gate electrode 94 and in a direction, for example, perpendicular to the direction of current flow between the source/drain regions 82 of the FinFET. Cross-section B-B is perpendicular to cross-section A-A and is along a longitudinal axis of the fin 52 and in a direction of, for example, a current flow between the source/drain regions 82 of the FinFET. Cross-section C-C is parallel to cross-section A-A and extends through a source/drain region of the FinFET. Subsequent figures refer to these reference cross-sections for clarity.

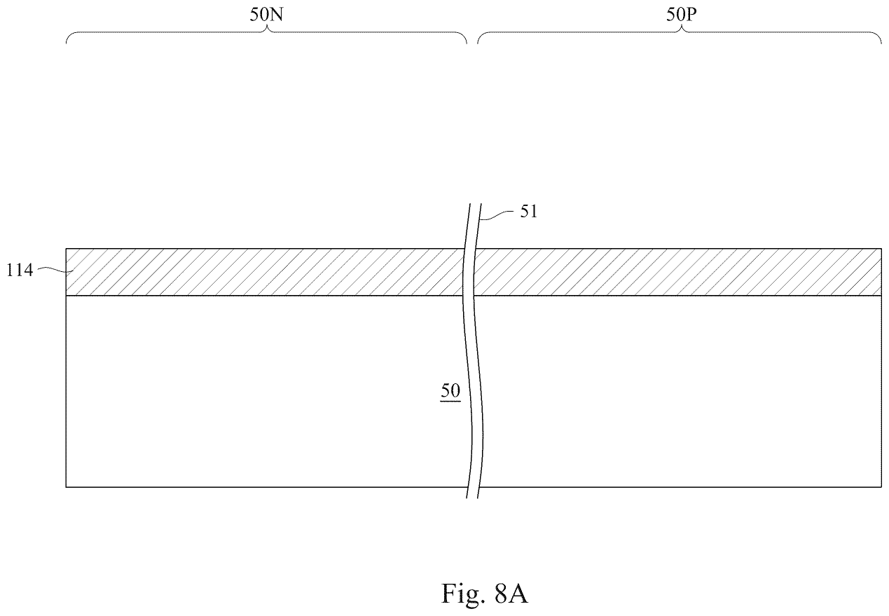

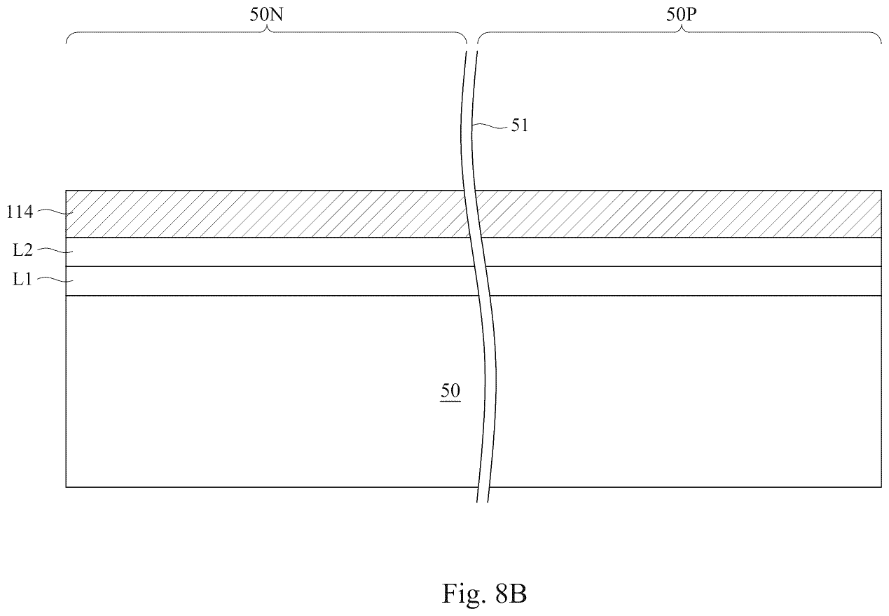

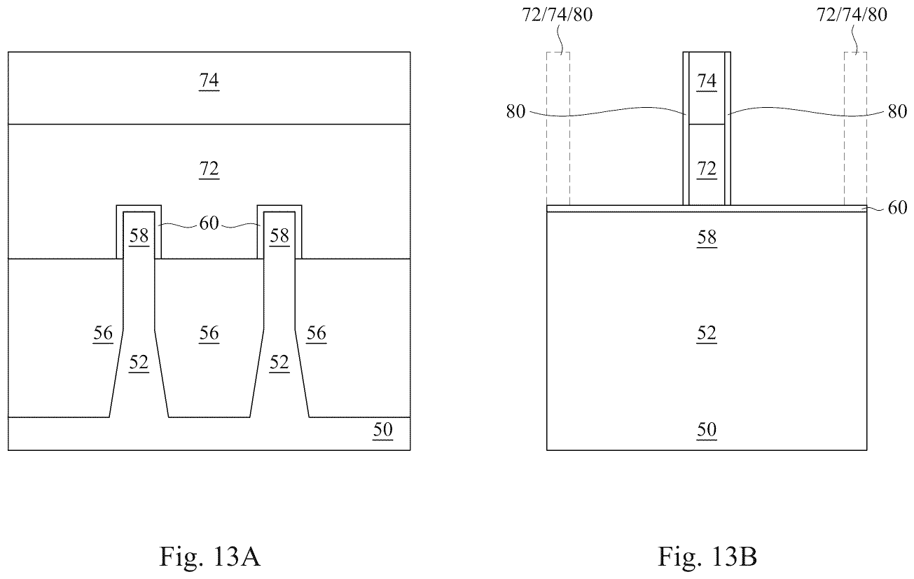

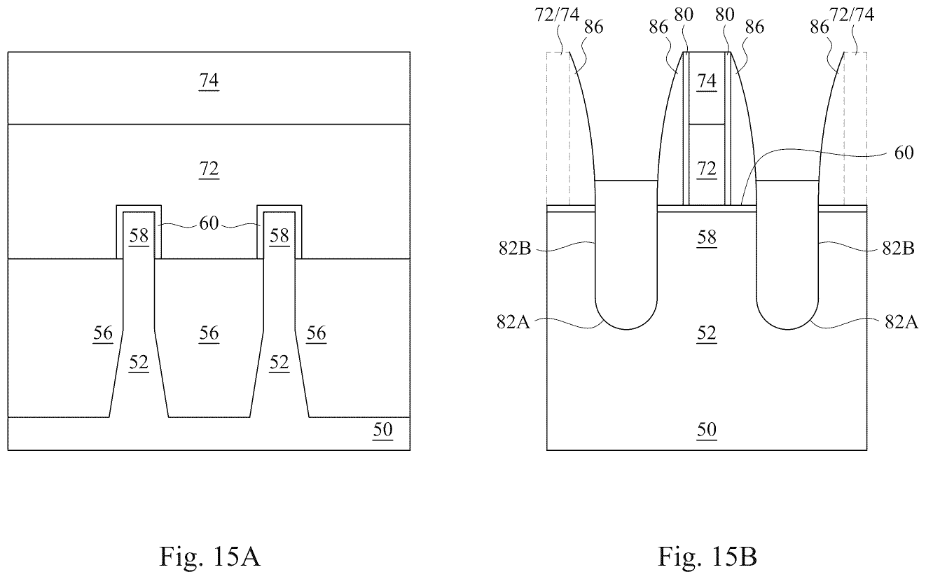

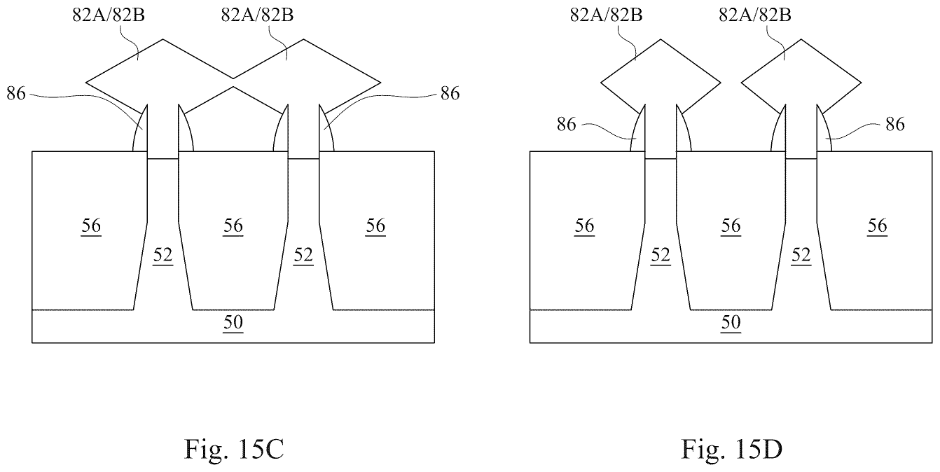

FIGS. 8A, 8B, 9-19C are cross-sectional views of intermediate stages in the manufacturing of FinFETs, in accordance with some embodiments. FIGS. 8A, 8B, 9-12 illustrate reference cross-section A-A illustrated in FIG. 7, except for multiple fins/FinFETs. FIGS. 13A, 14A, 15A, 16A, 17A, 18A and 19A are illustrated along reference cross-section A-A illustrated in FIG. 7, and FIGS. 13B, 14B, 15B, 16B, 17B, 18B and 19B are illustrated along a similar cross-section B-B illustrated in FIG. 7, except for multiple gate structures. FIGS. 15C and 15D are illustrated along reference cross-section C-C illustrated in FIG. 7, except for multiple fins/FinFETs.

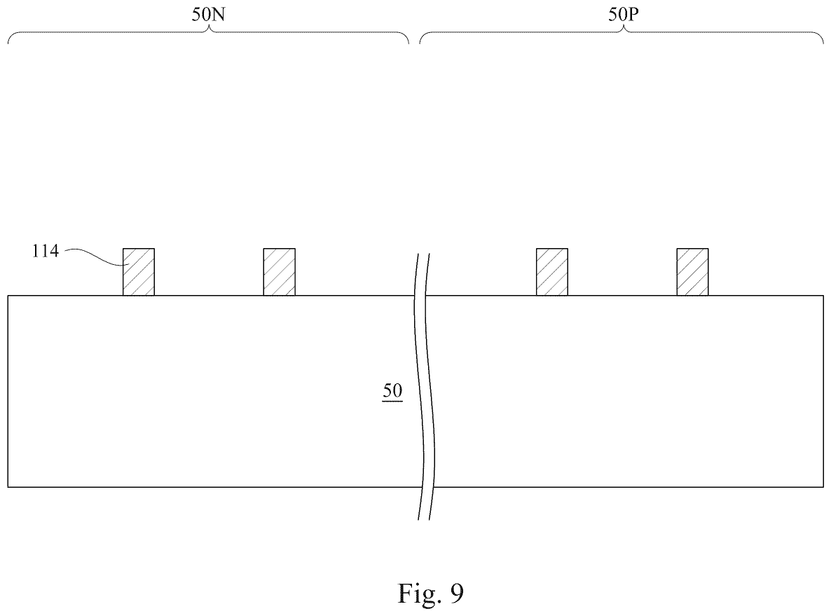

FIGS. 8A, 8B, 9 are cross-sectional view of forming a patterned photoresist layer in accordance with some embodiments. Reference is made to FIG. 8A. A substrate 50 is provided. The substrate 50 may be similar to the substrate 502 in FIG. 2A, and thus the description thereof is omitted herein. The substrate 50 has a region 50N and a region 50P. The region 50N can be for forming n-type devices, such as n-type MOS (NMOS) transistors, e.g., n-type FinFETs. The region 50P can be for forming p-type devices, such as p-type MOS (PMOS) transistors, e.g., p-type FinFETs. The region 50N may be physically separated from the region 50P (as illustrated by divider 51), and any number of device features (e.g., other active devices, doped regions, isolation structures, etc.) may be disposed between the region 50N and the region 50P.

Reference is made to FIG. 8A. In some embodiments, a photoresist composition is applied over the substrate to form a photoresist layer 114. A soft bake operation may then be performed to the photoresist layer 114. Composition and formation method of the photoresist layer 114 are discussed previously with regard to FIGS. 2A-2C, and thus the description thereof is omitted herein. Reference is made to FIG. 8B. In some other embodiments, a bottom layer Li and a middle layer L2 may be formed between the substrate 50 and the photoresist layer 114. The bottom layer L1 may be formed of a polymer in some embodiments. The bottom layer L1 may also be a bottom anti-reflective coating (BARC) layer. The middle layer L2 may include an inorganic material, which may be a nitride (such as silicon nitride), an oxynitride (such as silicon oxynitride), an oxide (such as silicon oxide), or the like. The middle layer L2 may have a high etching selectivity relative to the photoresist layer 114 and the bottom layer L1. The middle layer L2 and the bottom layer L1 may be blanket deposited sequentially using, for example, spin-on processes. Other processes and materials may be used.

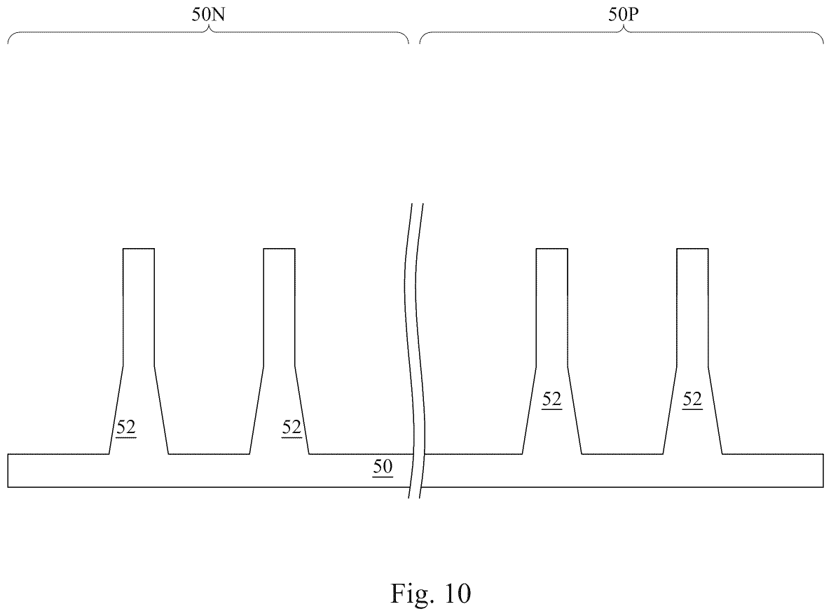

Reference is made to FIG. 9. In some embodiments, the photoresist is exposed by an actinic radiation and then developed. Reference is made to FIG. 10. The substrate 50 can be etched using the photoresist layer 114 as an etched mask. As discussed previously with regard to FIGS. 3-4, the reaction of extra photoacids generated at the boundary of the exposed regions of the photoresist layer 114 and the quencher malfunction at the boundary of the exposed regions of the photoresist layer 114 may be effectively inhibited by the radical quencher or radical scavenger of the moiety RQ because the secondary electrons can react with the radical quencher or radical scavenger and be quenched. Therefore, the LWR of the photoresist layer 114 used in EUV lithography can be improved. The photoresist layer 114 can be removed after etching the substrate 50 by using a suitable photoresist stripper solvent or by a photoresist ashing operation.

In FIG. 10, fins 52 are formed in the substrate 50. The fins 52 are semiconductor strips. In some embodiments, the fins 52 may be formed in the substrate 50 by etching trenches in the substrate 50. The etching may be any acceptable etch process, such as a reactive ion etch (RIE), neutral beam etch (NBE), the like, or a combination thereof. The etch may be anisotropic.

An insulation material 54 is formed over the substrate 50 and between neighboring fins 52. The insulation material 54 may be an oxide, such as silicon oxide, a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material 54 is silicon oxide formed by a FCVD process. An anneal process may be performed once the insulation material is formed. In an embodiment, the insulation material 54 is formed such that excess insulation material 54 covers the fins 52. Although the insulation material 54 is illustrated as a single layer, some embodiments may utilize multiple layers. For example, in some embodiments a liner (not shown) may first be formed along a surface of the substrate 50 and the fins 52. Thereafter, a fill material, such as those discussed above may be formed over the liner.

A removal process is applied to the insulation material 54 to remove excess insulation material 54 over the fins 52. In some embodiments, a planarization process such as a chemical mechanical polish (CMP), an etch-back process, combinations thereof, or the like may be utilized. The planarization process exposes the fins 52 such that top surfaces of the fins 52 and the insulation material 54 are level after the planarization process is complete. In embodiments in which a mask remains on the fins 52, the planarization process may expose the mask or remove the mask such that top surfaces of the mask or the fins 52, respectively, and the insulation material 54 are level after the planarization process is complete.

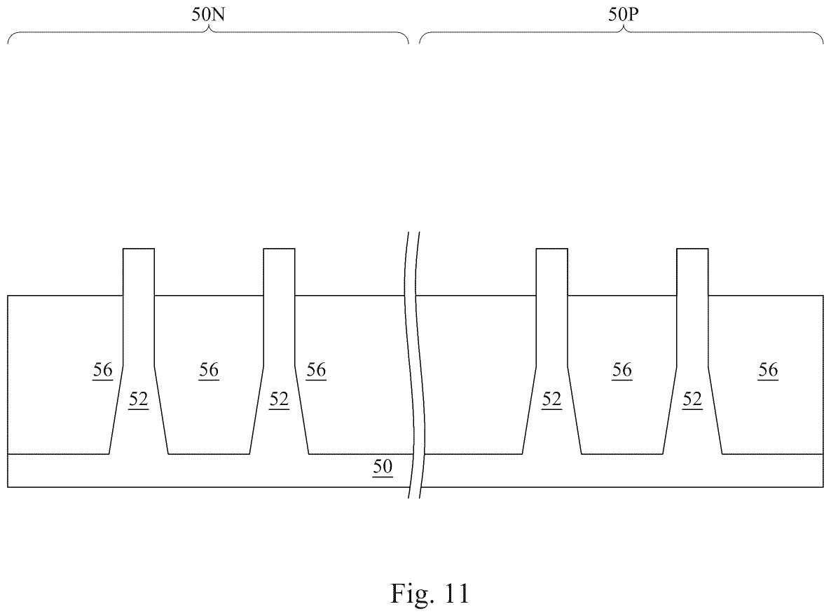

In FIG. 11, the insulation material 54 is recessed to form Shallow Trench Isolation (STI) regions 56. The insulation material 54 is recessed such that upper portions of fins 52 in the region 50N and in the region 50P protrude from between neighboring STI regions 56. Further, the top surfaces of the STI regions 56 may have a flat surface as illustrated, a convex surface, a concave surface (such as dishing), or a combination thereof. The top surfaces of the STI regions 56 may be formed flat, convex, and/or concave by an appropriate etch. The STI regions 56 may be recessed using an acceptable etching process, such as one that is selective to the material of the insulation material 54 (e.g., etches the material of the insulation material 54 at a faster rate than the material of the fins 52). For example, an oxide removal using, for example, dilute hydrofluoric (dHF) acid may be used.

Further in FIG. 11, appropriate wells (not shown) may be formed in the fins 52 and/or the substrate 50. In some embodiments, a P well may be formed in the region 50N, and an N well may be formed in the region 50P. In some embodiments, a P well or an N well are formed in both the region 50N and the region 50P.

In the embodiments with different well types, the different implant steps for the region 50N and the region 50P may be achieved using a photoresist or other masks (not shown). For example, a photoresist may be formed over the fins 52 and the STI regions 56 in the region 50N.

The photoresist is patterned to expose the region 50P of the substrate 50, such as a PMOS region. The photoresist can be formed by using a spin-on technique and can be patterned using acceptable photolithography techniques. Once the photoresist is patterned, an n-type impurity implant is performed in the region 50P, and the photoresist may act as a mask to substantially prevent n-type impurities from being implanted into the region 50N, such as an NMOS region. The n-type impurities may be phosphorus, arsenic, antimony, or the like. After the implant, the photoresist is removed, such as by an acceptable ashing process.

Following the implanting of the region 50P, a photoresist is formed over the fins 52 and the STI regions 56 in the region 50P. The photoresist is patterned to expose the region 50N of the substrate 50, such as the NMOS region. The photoresist can be formed by using a spin-on technique and can be patterned using acceptable photolithography techniques. Once the photoresist is patterned, a p-type impurity implant may be performed in the region 50N, and the photoresist may act as a mask to substantially prevent p-type impurities from being implanted into the region 50P, such as the PMOS region. The p-type impurities may be boron, boron fluoride, indium, or the like. After the implant, the photoresist may be removed, such as by an acceptable ashing process.

After the implants of the region 50N and the region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

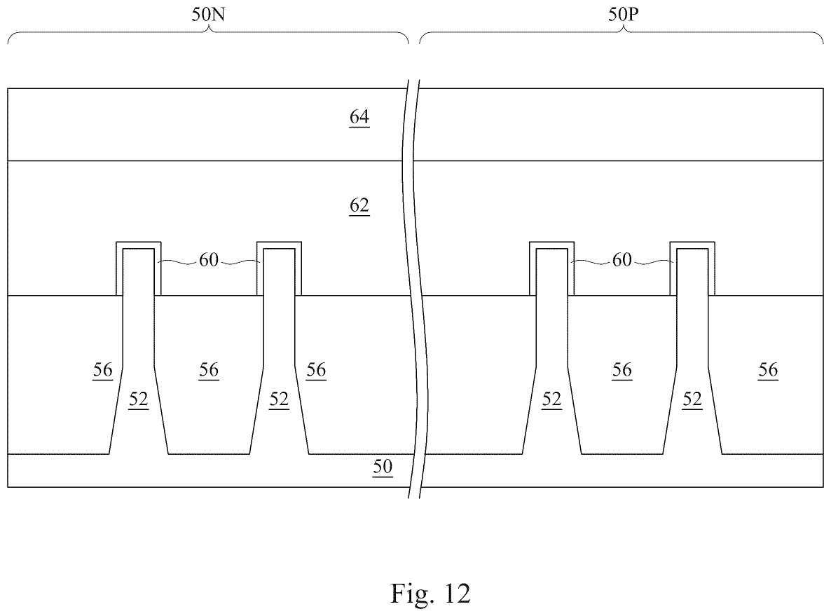

In FIG. 12, a dummy dielectric layer 60 is formed on the fins 52. The dummy dielectric layer 60 may be, for example, silicon oxide, silicon nitride, a combination thereof, or the like, and may be deposited or thermally grown according to acceptable techniques. A dummy gate layer 62 is formed over the dummy dielectric layer 60, and a mask layer 64 is formed over the dummy gate layer 62. The dummy gate layer 62 may be deposited over the dummy dielectric layer 60 and then planarized, such as by a CMP. The mask layer 64 may be deposited over the dummy gate layer 62. The dummy gate layer 62 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 62 may be deposited by physical vapor deposition (PVD), CVD, sputter deposition, or other techniques known and used in the art for depositing the selected material. The dummy gate layer 62 may be made of other materials that have a high etching selectivity from the etching of isolation regions. The mask layer 64 may include, for example, silicon nitride, silicon oxynitride, or the like. In this example, a single dummy gate layer 62 and a single mask layer 64 are formed across the region 50N and the region 50P. It is noted that the dummy dielectric layer 60 is shown covering only the fins 52 for illustrative purposes only. In some embodiments, the dummy dielectric layer 60 may be deposited such that the dummy dielectric layer 60 covers the STI regions 56, extending between the dummy gate layer 62 and the STI regions 56.

FIGS. 12 through 19C illustrate features in either of the region 50N and the region 50P. For example, the structures illustrated in FIGS. 12 through 19C may be applicable to both the region 50N and the region 50P. Differences (if any) in the structures of the region 50N and the region 50P are described in the text accompanying each figure.

In FIGS. 13A and 13B, the mask layer 64 (see FIG. 12) may be patterned using acceptable photolithography and etching techniques to form masks 74. The pattern of the masks 74 then may be transferred to the dummy gate layer 62. In some embodiments (not illustrated), the pattern of the masks 74 may also be transferred to the dummy dielectric layer 60 by an acceptable etching technique to form dummy gates 72. The dummy gates 72 cover respective channel regions 58 of the fins 52. The pattern of the masks 74 may be used to physically separate each of the dummy gates 72 from adjacent dummy gates. The dummy gates 72 may also have a lengthwise direction substantially perpendicular to the lengthwise direction of respective fins 52.

Further in FIGS. 13A and 13B, gate seal spacers 80 can be formed on exposed surfaces of the dummy gates 72, the masks 74, and/or the fins 52. A thermal oxidation or a deposition followed by an anisotropic etch may form the gate seal spacers 80. The gate seal spacers 80 may be formed of silicon oxide, silicon nitride, silicon oxynitride, or the like.

After the formation of the gate seal spacers 80, implants for lightly doped source/drain (LDD) regions (not explicitly illustrated) may be performed. In the embodiments with different device types, similar to the implants discussed above in FIG. 8A, a mask, such as a photoresist, may be formed over the region 50N, while exposing the region 50P, and appropriate type (e.g., p-type) impurities may be implanted into the exposed fins 52 in the region 50P. The mask may then be removed. Subsequently, a mask, such as a photoresist, may be formed over the region 50P while exposing the region 50N, and appropriate type impurities (e.g., n-type) may be implanted into the exposed fins 52 in the region 50N. The mask may then be removed. The n-type impurities may be the any of the n-type impurities previously discussed, and the p-type impurities may be the any of the p-type impurities previously discussed. An anneal may be used to repair implant damage and to activate the implanted impurities.

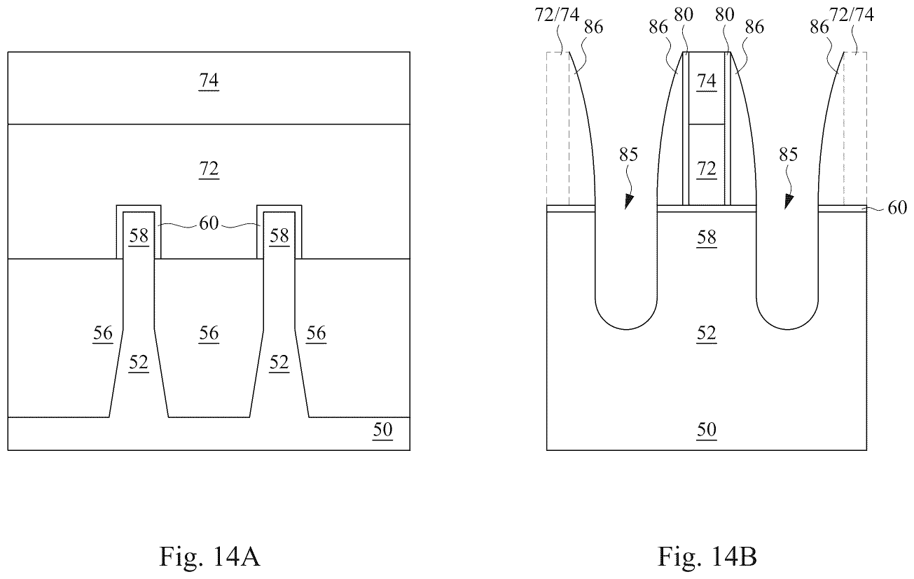

In FIGS. 14A and 14B, gate spacers 86 are formed on the gate seal spacers 80 along sidewalls of the dummy gates 72 and the masks 74. The gate spacers 86 may be formed by conformally depositing an insulating material and subsequently anisotropically etching the insulating material. The insulating material of the gate spacers 86 may be silicon oxide, silicon nitride, silicon oxynitride, silicon carbonitride, a combination thereof, or the like.

It is noted that the above disclosure generally describes a process of forming spacers and LDD regions. Other processes and sequences may be used. For example, fewer or additional spacers may be utilized, different sequence of steps may be utilized (e.g., the gate seal spacers 80 may not be etched prior to forming the gate spacers 86, yielding “L-shaped” gate seal spacers, spacers may be formed and removed, and/or the like.) Furthermore, the n-type and p-type devices may be formed using a different structures and steps. For example, LDD regions for n-type devices may be formed prior to forming the gate seal spacers 80 while the LDD regions for p-type devices may be formed after forming the gate seal spacers 80.

In FIGS. 15A-15D, source/drain regions 82 are formed in the fins 52 to exert stress in the respective channel regions 58, thereby improving performance. The source/drain regions 82 are formed in the fins 52 such that each dummy gate 72 is disposed between respective neighboring pairs of the source/drain regions 82. In some embodiments the source/drain regions 82 may extend into, and may also penetrate through, the fins 52. In some embodiments, the gate spacers 86 are used to separate the source/drain regions 82 from the dummy gates 72 by an appropriate lateral distance so that the source/drain regions 82 do not short out subsequently formed gates of the resulting FinFETs.

The formation of the source/drain regions 82 may be formed by distinct processes, such that the source/drain regions 82 may be different materials in each region and may be formed by distinct processes. Various masking steps may be used to mask and expose appropriate regions when using distinct processes.

Referring first to FIGS. 14A and 14B, a patterning process is performed on the fins 52 to form recesses 85 in source/drain regions of the fins 52. The patterning process may be performed in a manner that the recesses 85 are formed between neighboring dummy gate stacks 72/74 (in interior regions of the fins 52), or between an isolation region 56 and adjacent dummy gate stacks 72/74 (in end regions of the fins 52). In some embodiments, the patterning process may include a suitable anisotropic dry etching process, while using the dummy gate stacks 72/74, the gate spacers 86, and/or isolation regions 56 as a combined mask. The suitable anisotropic dry etching process may include a reactive ion etch (RIE), neutral beam etch (NBE), the like, or a combination thereof. In some embodiments where the RIE is used in the first patterning process, process parameters such as, for example, a process gas mixture, a voltage bias, and an radio frequency (RF) power may be chosen such that etching is predominantly performed using physical etching, such as ion bombardment, rather than chemical etching, such as radical etching through chemical reactions. In some embodiments, a voltage bias may be increased to increase energy of ions used in the ion bombardment process and, thus, increase a rate of physical etching. Since the physical etching is anisotropic in nature and the chemical etching is isotropic in nature, such an etching process has an etch rate in the vertical direction that is greater than an etch rate in the lateral direction.

In FIGS. 15A-15D, an epitaxial layer 82B of the source/drain regions 82 is grown in the recesses 85. In the region 50N, e.g., the NMOS region, the epitaxial layer 82B may include any acceptable material, such as appropriate for n-type FinFETs. For example, if the fin 52 is silicon, the epitaxial layer 82B in the region 50N may include materials exerting a tensile strain in the channel region 58, such as silicon, silicon carbide, phosphorous doped silicon carbide, silicon phosphide, or the like. The epitaxial layer 82B in the region 50N may have surfaces raised from respective surfaces of the fins 52 and may have facets. In some embodiments, the epitaxial layers 82A and 82B are epitaxially grown in a single continuous process where the gas flows of the various precursors are changed to form the different layers. In some embodiments, the epitaxial layers 82A and 82B are formed in separate, distinct epitaxial growth processes.

In the region 50P, e.g., the PMOS region, the epitaxial layer 82B may include any acceptable material, such as appropriate for p-type FinFETs. For example, if the fin 52 is silicon, the epitaxial layer 82B in the region 50P may comprise materials exerting a compressive strain in the channel region 58, such as silicon-germanium, boron doped silicon-germanium, germanium, germanium tin, or the like. The epitaxial layer 82B in the region 50P may also have surfaces raised from respective surfaces of the fins 52 and may have facets.

As a result of the epitaxy processes used to form the source/drain regions 82 in the region 50N and the region 50P, upper surfaces of the source/drain regions 82 have facets which expand laterally outward beyond sidewalls of the fins 52. In some embodiments, these facets cause adjacent epitaxial layers 82B of the source/drain regions 82 of a same FinFET to merge as illustrated by FIG. 15C. In other embodiments, adjacent epitaxial layers 82B of the source/drain regions 82 remain separated after the epitaxy process is completed as illustrated by FIG. 15D. In the embodiments illustrated in FIGS. 15C and 15D, gate spacers 86 are formed covering a portion of the sidewalls of the fins 52 that extend above the STI regions 56 thereby blocking the epitaxial growth. In some other embodiments, the spacer etch used to form the gate spacers 86 may be adjusted to remove the spacer material to allow the epitaxially grown region to extend to the surface of the STI region 56.

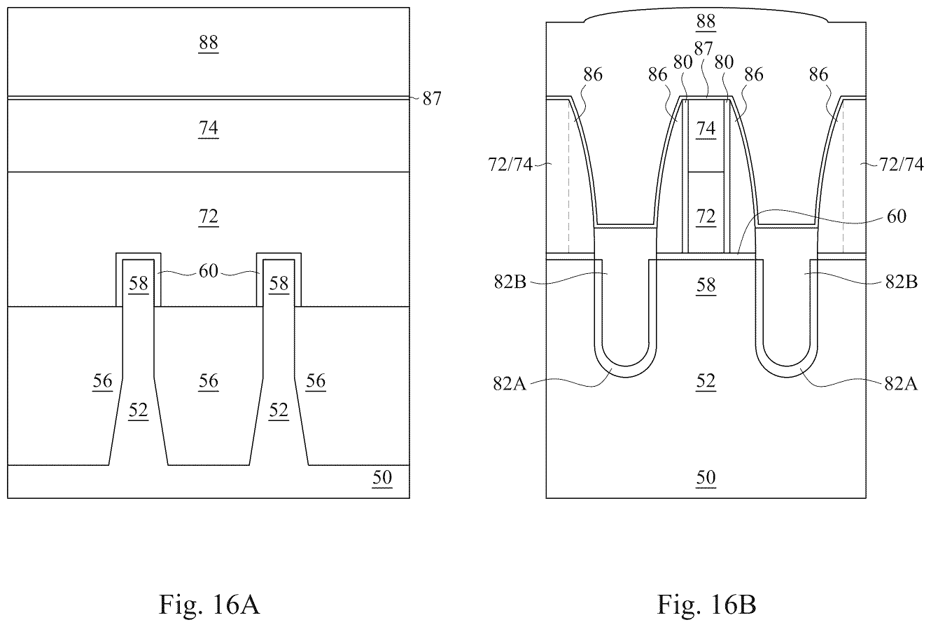

In FIGS. 16A and 16B, a first interlayer dielectric (ILD) 88 is deposited over the structure illustrated in FIGS. 15A and 15B. The first ILD 88 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 87 is disposed between the first ILD 88 and the epitaxial layer 82B of the source/drain regions 82, the masks 74, and the gate spacers 86. The CESL 87 may comprise a dielectric material, such as, silicon nitride, silicon oxide, silicon oxynitride, or the like, having a different etch rate than the material of the overlying first ILD 88.

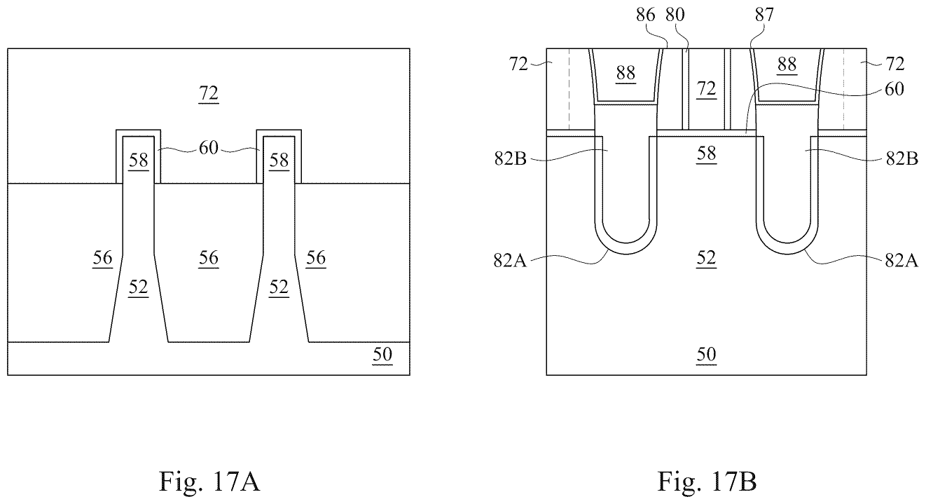

In FIGS. 17A and 17B, a planarization process, such as a CMP, may be performed to level the top surface of the first ILD 88 with the top surfaces of the dummy gates 72 or the masks 74. The planarization process may also remove the masks 74 on the dummy gates 72, and portions of the gate seal spacers 80 and the gate spacers 86 along sidewalls of the masks 74. After the planarization process, top surfaces of the dummy gates 72, the gate seal spacers 80, the gate spacers 86, and the first ILD 88 are level. Accordingly, the top surfaces of the dummy gates 72 are exposed through the first ILD 88. In some embodiments, the masks 74 may remain, in which case the planarization process levels the top surface of the first ILD 88 with the top surfaces of the top surface of the masks 74.

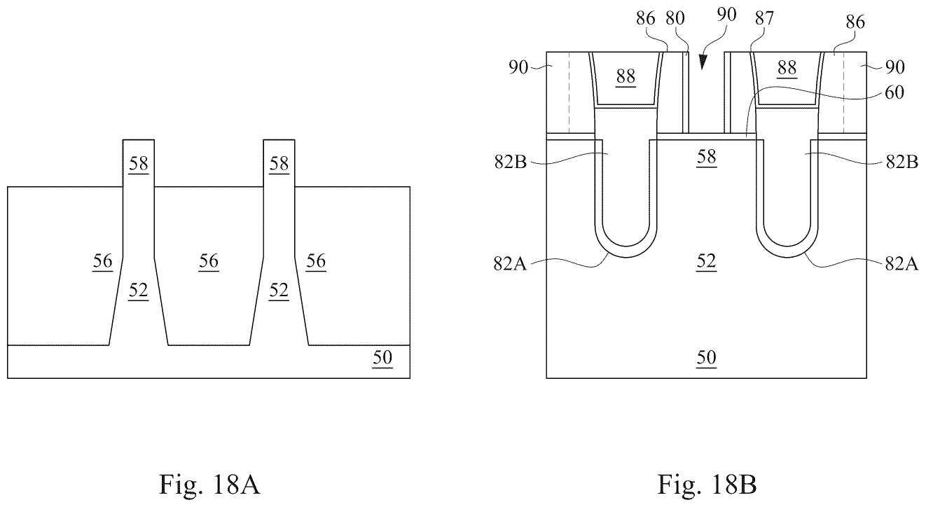

In FIGS. 18A and 18B, the dummy gates 72, and the masks 74 if present, are removed in an etching step(s), so that recesses 90 are formed. Portions of the dummy dielectric layer 60 in the recesses 90 may also be removed. In some embodiments, only the dummy gates 72 are removed and the dummy dielectric layer 60 remains and is exposed by the recesses 90. In some embodiments, the dummy dielectric layer 60 is removed from recesses 90 in a first region of a die (e.g., a core logic region) and remains in recesses 90 in a second region of the die (e.g., an input/output region). In some embodiments, the dummy gates 72 are removed by an anisotropic dry etch process. For example, the etching process may include a dry etch process using reaction gas(es) that selectively etch the dummy gates 72 without etching the first ILD 88 or the gate spacers 86. Each recess 90 exposes and/or overlies a channel region 58 of a respective fins 52. Each channel region 58 is disposed between neighboring pairs of the source/drain regions 82. During the removal, the dummy dielectric layer 60 may be used as an etch stop layer when the dummy gates 72 are etched. The dummy dielectric layer 60 may then be optionally removed after the removal of the dummy gates 72.

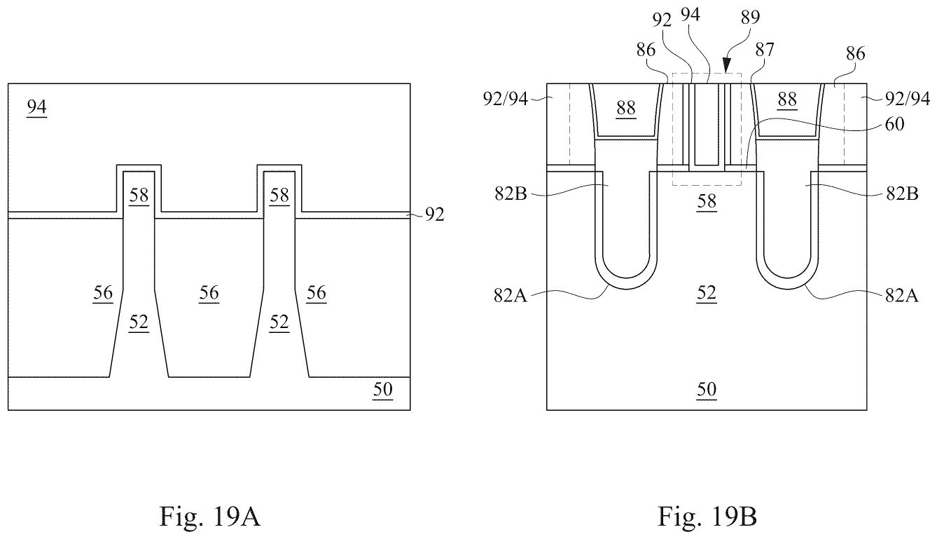

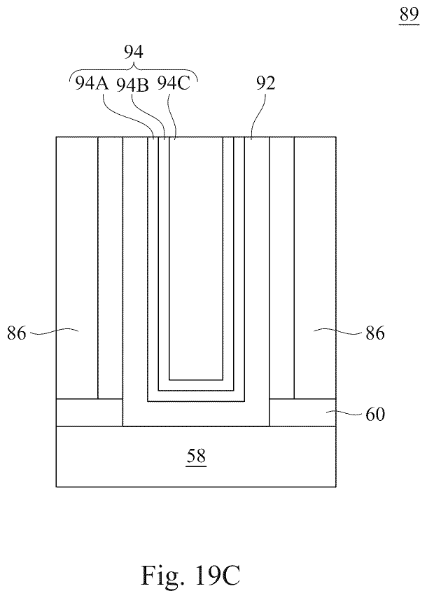

In FIGS. 19A and 19B, gate dielectric layers 92 and gate electrodes 94 are formed for replacement gates. FIG. 19C illustrates a detailed view of region 89 of FIG. 19B. Gate dielectric layers 92 are deposited conformally in the recesses 90, such as on the top surfaces and the sidewalls of the fins 52 and on sidewalls of the gate seal spacers 80/gate spacers 86. The gate dielectric layers 92 may also be formed on the top surface of the first ILD 88. In accordance with some embodiments, the gate dielectric layers 92 comprise silicon oxide, silicon nitride, or multilayers thereof. In some embodiments, the gate dielectric layers 92 include a high-k dielectric material, and in these embodiments, the gate dielectric layers 92 may have a k value greater than about 7.0, and may include a metal oxide or a silicate of hafnium, aluminum, zirconium, lanthanum, manganese, barium, titanium, lead, and combinations thereof. The formation methods of the gate dielectric layers 92 may include molecular-beam deposition (MBD), atomic layer deposition (ALD), PECVD, or the like. In embodiments where portions of the dummy dielectric layer 60 remains in the recesses 90, the gate dielectric layers 92 include a material of the dummy dielectric layer 60 (e.g., silicon oxide).

The gate electrodes 94 are deposited over the gate dielectric layers 92, respectively, and fill the remaining portions of the recesses 90. The gate electrodes 94 may include a metal-containing material such as titanium nitride, titanium oxide, tantalum nitride, tantalum carbide, cobalt, ruthenium, aluminum, tungsten, combinations thereof, or multi-layers thereof. For example, although a single layer gate electrode 94 is illustrated in FIG. 19B, the gate electrode 94 may comprise any number of liner layers 94A, any number of work function tuning layers 94B, and a fill material 94C as illustrated by FIG. 19C. After the filling of the recesses 90, a planarization process, such as a CMP, may be performed to remove the excess portions of the gate dielectric layers 92 and the material of the gate electrodes 94, which excess portions are over the top surface of the first ILD 88. The remaining portions of material of the gate electrodes 94 and the gate dielectric layers 92 thus form replacement gates of the resulting FinFETs. The gate electrodes 94 and the gate dielectric layers 92 may be collectively referred to as a “gate stack.” The gate and the gate stacks may extend along sidewalls of a channel region 58 of the fins 52.

The formation of the gate dielectric layers 92 in the region 50N and the region 50P may occur simultaneously such that the gate dielectric layers 92 in each region are formed from the same materials, and the formation of the gate electrodes 94 may occur simultaneously such that the gate electrodes 94 in each region are formed from the same materials. In some embodiments, the gate dielectric layers 92 in each region may be formed by distinct processes, such that the gate dielectric layers 92 may be different materials, and/or the gate electrodes 94 in each region may be formed by distinct processes, such that the gate electrodes 94 may be different materials. Various masking steps may be used to mask and expose appropriate regions when using distinct processes.

Embodiments may achieve advantages. One advantage is that by including the radical quencher or radical scavenger in the photoresist, the reaction of the extra photoacid generated at the boundary of the exposed regions of the photoresist and the quencher malfunction at the boundary of the exposed regions of the photoresist may effectively be inhibited by the radical quencher or radical scavenger because the secondary electrons can react and be quenched by the radical quencher or radical scavenger. Therefore, the LWR of the photoresist used in EUV lithography can be improved.

In some embodiments, a photoresist composition comprises a polymer, a photo acid generator (PAG) and a solvent. The polymer comprises a moiety comprising a radical quencher. The PAG is sensitive to extreme ultraviolet (EUV) radiation. In some embodiments, the polymer comprises a phenolic group. In some embodiments, the radical quencher comprises a core containing C3 to C80 saturated or unsaturated hydrocarbon ring or C2 to C80 heterocyclic saturated or unsaturated hydrocarbon. In some embodiments, the radical quencher further comprises a group connected to the core as a substituent, wherein the group comprises a bond dissociation energy in a range from about 10 kcal/mol to about 1000 kcal/mol. In some embodiments, the group comprises OH, SH, SeH, TeH, O—R, S—R, Se—R, Te—R, NH₂, NHR, NR₂, and wherein in O—R, S—R, Se—R, Te—R, NHR, NR₂, R is C1 to C20 alkyl group, cycloalkyl group, hydroxylalkyl group, alkoxy group, alkoxyl alkyl group, acetyl group, acetylalkyl group, carboxyl group, alky carboxyl group, cycloalkyl carboxyl group, C2 to C20 saturated or unsaturated hydrocarbon ring, C1 to C20 hetero hydrocarbon, C2 to C20 heterocyclic hydrocarbon. In some embodiments, the radical quencher further comprises a plurality of groups connected to the core as substituents, wherein one of the groups comprises a bond dissociation energy in a range from about 10 kcal/mol to about 1000 kcal/mol. In some embodiments, one of the plurality of groups comprises OH, SH, SeH, TeH, O—R, S—R, Se—R, Te—R, NH₂, NHR, NR₂, and wherein in O—R, S—R, Se—R, Te—R, NHR, NR₂, R is C1 to C20 alkyl group, cycloalkyl group, hydroxylalkyl group, alkoxy group, alkoxyl alkyl group, acetyl group, acetylalkyl group, carboxyl group, alky carboxyl group, cycloalkyl carboxyl group, C2 to C20 saturated or unsaturated hydrocarbon ring, C1 to C20 hetero hydrocarbon, C2 to C20 heterocyclic hydrocarbon. In some embodiments, the photoresist composition further comprises a photo decomposable quencher (PDQ).

In some embodiments, a lithography method comprises the following steps. A target layer is formed over a substrate. A photoresist composition is applied over the target layer to form a photoresist layer, wherein the photoresist composition comprises a polymer, a photo acid generator (PAG) sensitive to extreme ultraviolet (EUV) radiation, a radical quencher and a solvent. The radical quencher comprises a core containing C3 to C80 saturated or unsaturated hydrocarbon ring or C2 to C80 heterocyclic saturated or unsaturated hydrocarbon, and a group connected to the core as a substituent, wherein the group comprises a bond dissociation energy in a range from about 10 kcal/mol to about 1000 kcal/mol. The photoresist layer is exposed. The photoresist layer is developed. The target layer is etched using the photoresist layer as an etch mask. In some embodiments, the polymer comprises formulae (a1)-(a4):

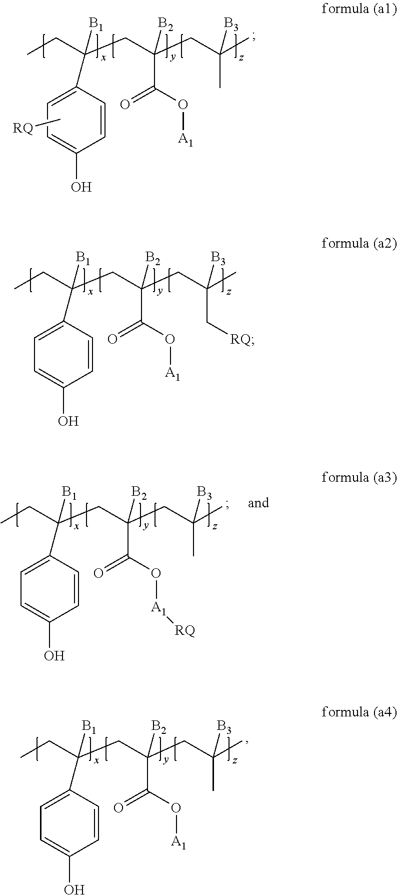

A₁ is an acid labile group (ALG), x+y+z=1, B₁, B₂, B₃ is CH₃ or H, and RQ is the radical quencher. In some embodiments, the radical quencher is not bonded to the polymer. In some embodiments, the radical quencher comprises formula (bi):

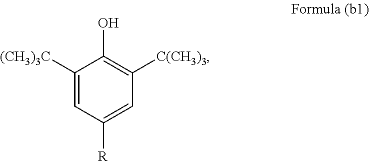

in the formula (b1), R is C1 to C20 alkyl group, cycloalkyl group, hydroxylalkyl group, alkoxy group, alkoxyl alkyl group, acetyl group, acetylalkyl group, carboxyl group, alky carboxyl group, cycloalkyl carboxyl group, C2 to C20 saturated or unsaturated hydrocarbon ring, C1 to C20 hetero hydrocarbon, C2 to C20 heterocyclic hydrocarbon. In some embodiments, the PAG comprises a formula (e1):

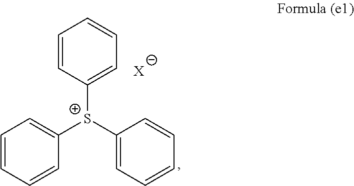

where X is an anion including R—SO₃⁻, R in the R—SO₃⁻ is hydrogen atom, an alkyl group having 1 to 20 carbon atoms, an aminoalkyl group having 1 to 20 carbon atoms, a hydroxyalkyl group having 1 to 20 carbon atoms, or a substituted or unsubstituted aryl group having 1 to 20 carbon atoms. In some embodiments, the photoresist composition further comprises a photo decomposable quencher (PDQ). In some embodiments, the PDQ comprises a formula (e1):

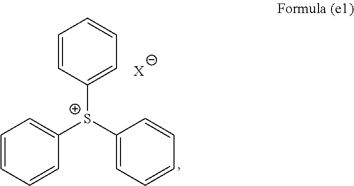

where X is an anion including R—COO⁻, R in R—COO⁻ is hydrogen atom, an alkyl group having 1 to 20 carbon atoms, an aminoalkyl group having 1 to 20 carbon atoms, a hydroxyalkyl group having 1 to 20 carbon atoms, or a substituted or unsubstituted aryl group having 1 to 20 carbon atoms.

In some embodiments, an extreme ultraviolet lithography (EUVL) method comprises the following steps. A droplet generator is turned on to eject a metal droplet toward a zone of excitation in front of a collector. A laser source is turned on to emit a laser toward the zone of excitation, such that the metal droplet is heated by the laser to generate EUV radiation. The EUV radiation is guided, by using one or more first optics, toward a reflective mask in an exposure device. The EUV radiation is guided, by using one or more second optics, reflected from the reflective mask toward a photoresist layer coated substrate in the exposure device. The photoresist layer is formed by applying a photoresist composition comprising a polymer comprises a moiety comprising a radical quencher. In some embodiments, the radical quencher comprises a core containing C3 to C80 saturated or unsaturated hydrocarbon ring or C2 to C80 heterocyclic saturated or unsaturated hydrocarbon. In some embodiments, the radical quencher further comprises a group connected to the core as a substituent, wherein the group comprises a bond dissociation energy in a range from about 10 kcal/mol to about 1000 kcal/mol. In some embodiments, the group comprises OH, SH, SeH, TeH, O—R, S—R, Se—R, Te—R, NH₂, NHR, NR₂, and wherein in O—R, S—R, Se—R, Te—R, NHR, NR₂, R is C1 to C20 alkyl group, cycloalkyl group, hydroxylalkyl group, alkoxy group, alkoxyl alkyl group, acetyl group, acetylalkyl group, carboxyl group, alky carboxyl group, cycloalkyl carboxyl group, C2 to C20 saturated or unsaturated hydrocarbon ring, C1 to C20 hetero hydrocarbon, C2 to C20 heterocyclic hydrocarbon. In some embodiments, the radical quencher further comprises a plurality of groups connected to the core as substituents, wherein one of the groups comprises a bond dissociation energy in a range from about 10 kcal/mol to about 1000 kcal/mol.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A photoresist composition, comprising:
a polymer, wherein the polymer comprises a moiety comprising a radical quencher;
a photo acid generator (PAG) sensitive to extreme ultraviolet (EUV) radiation; and
a solvent.

2. The photoresist composition of claim 1, wherein the polymer comprises a phenolic group.

3. The photoresist composition of claim 1, wherein the radical quencher comprises:
a core containing C3 to C80 saturated or unsaturated hydrocarbon ring or C2 to C80 heterocyclic saturated or unsaturated hydrocarbon.

4. The photoresist composition of claim 3, wherein the radical quencher further comprises:
a group connected to the core as a substituent, wherein the group comprises a bond dissociation energy in a range from about 10 kcal/mol to about 1000 kcal/mol.

5. The photoresist composition of claim 4, wherein the group comprises OH, SH, SeH, TeH, O—R, S—R, Se—R, Te—R, NH₂, NHR, NR₂, and wherein in O—R, S—R, Se—R, Te—R, NHR, NR₂, R is C1 to C20 alkyl group, cycloalkyl group, hydroxylalkyl group, alkoxy group, alkoxyl alkyl group, acetyl group, acetylalkyl group, carboxyl group, alky carboxyl group, cycloalkyl carboxyl group, C2 to C20 saturated or unsaturated hydrocarbon ring, C1 to C20 hetero hydrocarbon, C2 to C20 heterocyclic hydrocarbon.

6. The photoresist composition of claim 3, wherein the radical quencher further comprises:
a plurality of groups connected to the core as substituents, wherein one of the groups comprises a bond dissociation energy in a range from about 10 kcal/mol to about 1000 kcal/mol.

7. The photoresist composition of claim 6, wherein one of the plurality of groups comprises OH, SH, SeH, TeH, O—R, S—R, Se—R, Te—R, NH₂, NHR, NR₂, and wherein in O—R, S—R, Se—R, Te—R, NHR, NR₂, R is C1 to C20 alkyl group, cycloalkyl group, hydroxylalkyl group, alkoxy group, alkoxyl alkyl group, acetyl group, acetylalkyl group, carboxyl group, alky carboxyl group, cycloalkyl carboxyl group, C2 to C20 saturated or unsaturated hydrocarbon ring, C1 to C20 hetero hydrocarbon, C2 to C20 heterocyclic hydrocarbon.

8. The photoresist composition of claim 1, further comprising:
a photo decomposable quencher (PDQ).

9. A lithography method, comprising:
forming a target layer over a substrate;
applying a photoresist composition over the target layer to form a photoresist layer, wherein the photoresist composition comprises:
a polymer;
a photo acid generator (PAG) sensitive to extreme ultraviolet (EUV) radiation;
a radical quencher comprises:
a core containing C3 to C80 saturated or unsaturated hydrocarbon ring or C2 to C80 heterocyclic saturated or unsaturated hydrocarbon; and
a group connected to the core as a substituent, wherein the group comprises a bond dissociation energy in a range from about 10 kcal/mol to about 1000 kcal/mol; and
a solvent;
exposing the photoresist layer;
developing the photoresist layer; and
etching the target layer using the photoresist layer as an etch mask.

10. The method of claim 9, wherein the polymer comprises formulae (a1)-(a4): 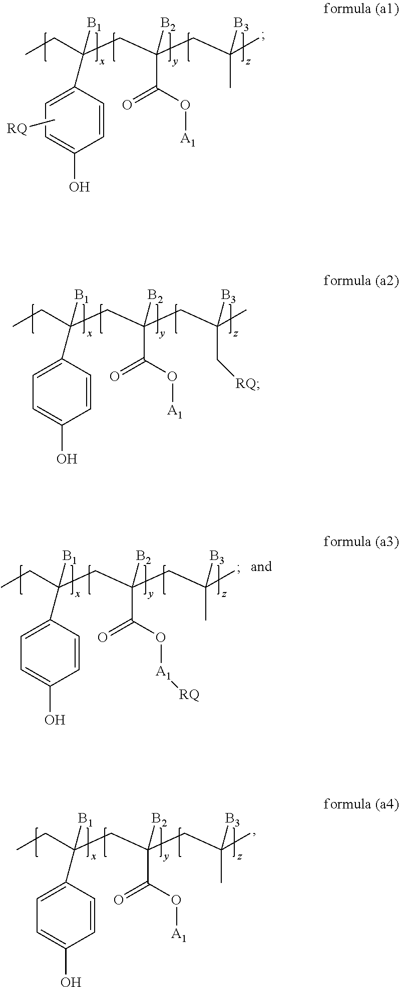
and wherein:
A₁ is an acid labile group (ALG), x+y+z=1, B₁, B₂, B₃ is CH₃ or H, and RQ is the radical quencher.

11. The method of claim 9, wherein the radical quencher is not bonded to the polymer.

12. The method of claim 9, wherein the radical quencher comprises formula (bi): 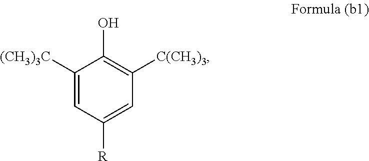
in the formula (b1), R is C1 to C20 alkyl group, cycloalkyl group, hydroxylalkyl group, alkoxy group, alkoxyl alkyl group, acetyl group, acetylalkyl group, carboxyl group, alky carboxyl group, cycloalkyl carboxyl group, C2 to C20 saturated or unsaturated hydrocarbon ring, C1 to C20 hetero hydrocarbon, C2 to C20 heterocyclic hydrocarbon.

13. The method of claim 9, wherein the PAG comprises a formula (e1): 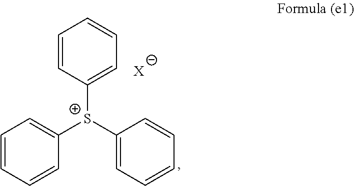
where X is an anion including R—SO₃⁻, R in the R—SO₃⁻ is hydrogen atom, an alkyl group having 1 to 20 carbon atoms, an aminoalkyl group having 1 to 20 carbon atoms, a hydroxyalkyl group having 1 to 20 carbon atoms, or a substituted or unsubstituted aryl group having 1 to 20 carbon atoms.

14. The method of claim 9, wherein the photoresist composition further comprises:
a photo decomposable quencher (PDQ).

15. The method of claim 14, wherein the PDQ comprises a formula (e1): 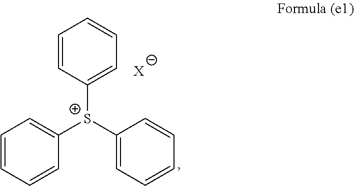
where X is an anion including R—COO⁻, R in R—COO⁻ is hydrogen atom, an alkyl group having 1 to 20 carbon atoms, an aminoalkyl group having 1 to 20 carbon atoms, a hydroxyalkyl group having 1 to 20 carbon atoms, or a substituted or unsubstituted aryl group having 1 to 20 carbon atoms.

16. An extreme ultraviolet lithography (EUVL) method, comprising:
turning on a droplet generator to eject a metal droplet toward a zone of excitation in front of a collector;
turning on a laser source to emit a laser toward the zone of excitation, such that the metal droplet is heated by the laser to generate EUV radiation;
guiding the EUV radiation, by using one or more first optics, toward a reflective mask in an exposure device; and
guiding the EUV radiation, by using one or more second optics, reflected from the reflective mask toward a photoresist layer coated substrate in the exposure device,
wherein the photoresist layer is formed by applying a photoresist composition comprising a polymer comprises a moiety comprising a radical quencher.

17. The EUVL method of claim 16, wherein the radical quencher comprises:
a core containing C3 to C80 saturated or unsaturated hydrocarbon ring or C2 to C80 heterocyclic saturated or unsaturated hydrocarbon.

18. The EUVL method of claim 17, wherein the radical quencher further comprises:
a group connected to the core as a substituent, wherein the group comprises a bond dissociation energy in a range from about 10 kcal/mol to about 1000 kcal/mol.

19. The EUVL method of claim 18, wherein the group comprises OH, SH, SeH, TeH, O—R, S—R, Se—R, Te—R, NH₂, NHR, NR₂, and wherein in O—R, S—R, Se—R, Te—R, NHR, NR₂, R is C1 to C20 alkyl group, cycloalkyl group, hydroxylalkyl group, alkoxy group, alkoxyl alkyl group, acetyl group, acetylalkyl group, carboxyl group, alky carboxyl group, cycloalkyl carboxyl group, C2 to C20 saturated or unsaturated hydrocarbon ring, C1 to C20 hetero hydrocarbon, C2 to C20 heterocyclic hydrocarbon.

20. The EUVL method of claim 17, wherein the radical quencher further comprises:
a plurality of groups connected to the core as substituents, wherein one of the groups comprises a bond dissociation energy in a range from about 10 kcal/mol to about 1000 kcal/mol.
